(19) United States
(12) Patent Application Publication
(10) Pub. No.: US 2024/0113114 A1
(43) Pub. Date: Apr. 4, 2024

(54) METHODS FOR FORMING HIGH PERFORMANCE 3D NANO SHEET DEVICES

(71) Applicant: Tokyo Electron Limited, Tokyo (JP)

(72) Inventors: H. Jim Fulford, Albany, NY (US); Mark I. Gardner, Albany, NY (US)

(73) Assignee: Tokyo Electron Limited, Tokyo (JP)

(21) Appl. No.: 17/950,870

(22) Filed: Sep. 22, 2022

(51) Int. Cl. H01L 27/092; H01L 21/8238; H01L 29/06; H01L 29/423; H01L 29/786

(52) U.S. Cl. CPC H01L 27/092; H01L 21/823814; H01L 29/0673; H01L 29/42392; H01L 29/78696

(57) ABSTRACT

Semiconductor devices and corresponding methods of manufacture are disclosed. The method includes forming a first stack over a substrate including first dielectric layers and second dielectric layers alternately stacked on top of one another. The method includes replacing first, second, and third portions of the first stack with first, second, and third dielectric structures, respectively. The method includes replacing the first dielectric structure with a second stack including first semiconductor layers and second semiconductor layers alternately stacked on top of one another. The method includes removing a portion of the second dielectric structure and a portion of the third dielectric structure. The method includes exposing sidewalls of each of the second semiconductor layers. The method includes forming a pair of first epitaxial structures and a pair of second epitaxial structures in contact with the exposed sidewalls of a lower one and an upper one of the second semiconductor layers, respectively.

### FIELD OF THE DISCLOSURE

This disclosure relates to microelectronic devices including semiconductor devices, transistors, and integrated circuits, including methods of microfabrication.

### BACKGROUND

In the manufacture of semiconductor devices (especially on the microscopic scale), various fabrication processes are executed, for example, film-forming depositions, etch mask creation, patterning, material etching and removal, and doping treatments, among others. These processes can be performed repeatedly to form desired semiconductor device elements on a substrate. Historically, with microfabrication, transistors have been created in one plane, with wiring or metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

Three-dimensional integration (e.g., the vertical stacking of multiple devices) aims to overcome scaling limitations experienced in planar devices by increasing transistor density in volume rather than area. Three-dimensional integration as applied to random logic designs is substantially more difficult than alternative approaches. Three-dimensional integration for logic chips (e.g., CPU (central processing unit), GPU (graphics processing unit), FPGA (field programmable gate array, SoC (System on a Chip), etc.) are being pursued.

The techniques described herein include methods and devices for 3D fabrication of semiconductor devices. Specifically, techniques may include 3D stacking with integrated channel and source/drain (S/D) structures/regions (e.g., cut with a mask using 3D channel nanosheet core formation for enhanced alignment). The 3D structure for the semiconductor device can include an integrated metal self-aligned extension for source and drain epitaxial (EPI) hookup (e.g., for 3D horizontal device integration). The techniques can achieve or be used to fabricate both 3D complementary metal-oxide semiconductor (CMOS) and side-by-side devices. The build or structure constructed using the techniques can include at least one of 3D cell designs or self-aligned S/D metal regions extensions (e.g., for 3D horizontal device integration) to achieve high-performance 3D semiconductor devices in at least one or both channel and S/D (e.g., EPI) regions with N number of layers in the stack of the semiconductor device(s). By utilizing the techniques of the technical solution, fewer operations/processes can be performed for fabricating the 3D semiconductor devices. Further, connection of the S/D structures associated with NMOS and PMOS devices can be achieved to function as an inverter.

Of course, the order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

At least one aspect of the present disclosure is directed to a method for fabricating semiconductor devices. The method includes forming a first stack over a substrate, the first stack including a plurality of first dielectric layers and a plurality of second dielectric layers alternately stacked on top of one another. The method includes replacing a first portion, a second portion, and a third portion of the first stack with a first dielectric structure, a second dielectric structure, and a third dielectric structure, respectively. The first to third dielectric structures each continuously extend through the first stack. The method includes replacing the first dielectric structure with a second stack, the second stack including a plurality of first semiconductor layers and a plurality of second semiconductor layers alternately stacked on top of one another. The method includes removing a portion of the second dielectric structure. The method includes removing a portion of the third dielectric structure. The method includes exposing, through the removed portion of the second dielectric structure and the removed portion of the third dielectric structure, sidewalls of each of the plurality of second semiconductor layers, respectively. The method includes forming a pair of first epitaxial structures in contact with the exposed sidewalls of a lower one of the second semiconductor layers, respectively. The method includes forming a pair of second epitaxial structures in contact with the exposed sidewalls of an upper one of the second semiconductor layers, respectively.

In various arrangements, the pair of first epitaxial structures and the pair of second epitaxial structures are concurrently formed. The pair of first epitaxial structures and the pair of second epitaxial structures have a same conductive type. The method includes forming, through the removed portion of the second dielectric structure and the removed portion of the third dielectric structure, a pair of metal structures in electrical contact with the pair of first epitaxial structures, respectively, and with the pair of second epitaxial structures, respectively.

In some arrangements, the method includes replacing the first semiconductor layers with a gate structure that is around each of the second semiconductor layers. In some cases, the step of replacing the first dielectric structure with a second stack includes: epitaxially growing a third semiconductor layer from the substrate; epitaxially growing a lower one of the first semiconductor layers; epitaxially growing the lower second semiconductor layer; epitaxially growing a middle one of the first semiconductor layers; epitaxially growing the upper second semiconductor layer; and epitaxially growing an upper one of the first semiconductor layers. The method includes replacing the third semiconductor layer with a third dielectric layer to electrically isolate the second stack from the substrate.

In some implementations, the second dielectric structure and the third dielectric structure are disposed on opposite sides of the first dielectric structure, respectively. In some cases, the pair of first epitaxial structures and the pair of second epitaxial structures each have a first thickness thinner than a second thickness of each the second semiconductor layers.

At least one aspect of the present disclosure is directed to a method for microfabrication. The method includes forming a first stack over a substrate, the first stack including a plurality of first dielectric layers and a plurality of second dielectric layers alternately stacked on top of one another. The method includes replacing a first portion, a second portion, a third portion, a fourth portion, a fifth portion, and a sixth portion of the first stack with a first dielectric structure, a second dielectric structure, a third dielectric structure, a fourth dielectric structure, a fifth dielectric structure, and a sixth dielectric structure, respectively. The first to sixth dielectric structures each continuously extend through the first stack, the first dielectric structure is interposed between the second and third dielectric structures, and the fourth dielectric structure is interposed between the fifth and sixth dielectric structures. The method includes replacing the first dielectric structure with a second stack and replacing the fourth dielectric structure with a third stack, the second stack and third stack each including a plurality of first semiconductor layers and a plurality of second semiconductor layers alternately stacked on top of one another. The method includes forming, through at least respectively removed portions of the second dielectric structure and the third dielectric structure, a plurality of pairs of first epitaxial structures in contact with sidewalls of the second semiconductor layers of the second stack, respectively. The method includes forming, through at least respectively removed portions of the fifth dielectric structure and the sixth dielectric structure, a plurality of pairs of second epitaxial structures in contact with sidewalls of the second semiconductor layers of the second stack, respectively.

In various arrangements, the pairs of first epitaxial structures each have a first conductive type and the pairs of second epitaxial structures each have a second conductive type. The first conductive type is opposite to the second conductive type.

In some arrangements, the method includes replacing the first semiconductor layers of the second stack with a first gate structure that is around each of its second semiconductor layers. The method includes replacing the first semiconductor layers of the third stack with a second gate structure that is around each of its second semiconductor layers. In some cases, the first gate structure has a first conductive type and the second gate structure has a second conductive type. In some cases, the first conductive type is opposite to the second conductive type.

In some implementations, the step of replacing the first dielectric structure with a second stack and replacing the fourth dielectric structure with a third stack comprises: epitaxially growing, in each of the first and fourth portions of the first stack, a third semiconductor layer from the substrate; epitaxially growing, in each of the first and fourth portions of the first stack, a lower one of the first semiconductor layers; epitaxially growing, in each of the first and fourth portions of the first stack, the lower second semiconductor layer; epitaxially growing, in each of the first and fourth portions of the first stack, a middle one of the first semiconductor layers; epitaxially growing, in each of the first and fourth portions of the first stack, the upper second semiconductor layer; and epitaxially growing, in each of the first and fourth portions of the first stack, an upper one of the first semiconductor layers.

In various implementations, the method includes replacing the third semiconductor layer in each of the first and fourth portions of the first stack with a respective third dielectric layer. In some implementations, the method includes forming, through the respectively removed portions of the second dielectric structure and the third dielectric structure, a pair of first metal structures in electrical contact with each of the pairs of first epitaxial structures, respectively; and forming, through the respectively removed portions of the fifth dielectric structure and the sixth dielectric structure, a pair of second metal structures in electrical contact with each of the pairs of second epitaxial structures, respectively.

Yet another aspect of the present disclosure is directed to a semiconductor device. The semiconductor device includes a plurality of first semiconductor layers vertically spaced from one another. The semiconductor device includes a plurality of second semiconductor layers vertically spaced from one another, wherein the second semiconductor layers are laterally spaced from the first semiconductor layers. The semiconductor device includes a plurality of pairs of first epitaxial structures vertically spaced from one another, wherein each of the pairs of first epitaxial structures are in contact with a corresponding one of the first semiconductor layers, respectively. The semiconductor device includes a plurality of pairs of second epitaxial structures vertically spaced from one another, wherein each of the pairs of second epitaxial structures are in contact with a corresponding one of the second semiconductor layers, respectively. The semiconductor device includes a first gate structure disposed around each of the first semiconductor layers. The semiconductor device includes a second gate structure disposed around each of the second semiconductor layers.

In various arrangements, the pairs of first epitaxial structures each have a first conductive type, and the pairs of second epitaxial structures each have a second conductive type. In some cases, the first conductive type is opposite to the second conductive type.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1-26 show views of a first process flow to manufacture semiconductor devices with an integrated channel, source, and drain, according to an embodiment;

FIGS. 27-51 show views of a second process flow to manufacture semiconductor devices with an integrated channel, source, and drain for CMOS, according to an embodiment;

FIGS. 52-53 show views of a third process flow to manufacture semiconductor devices with an integrated channel, source, and drain for an inverter, according to an embodiment; and

FIG. 54 shows a flow diagram of an example method for microfabrication using the process flows described in connection with FIGS. 1-53, according to an embodiment.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Techniques herein include methods and devices for 3D fabrication of semiconductor devices. Specifically, techniques include self-aligned metal routing for vertical channel transistors achieved with 360-degree symmetry for 3D vertical transistors. Excellent compact circuit layout is obtained with such techniques. Techniques herein can be used for any geometry device (e.g., circular, rectangular, ellipse, etc.). As used herein, the value N refers to the number of alternating layers of metal and dielectric are utilized to form various transistor devices. For example, some embodiments herein show an N=2 3D stack, but techniques apply to any number of N layers for any number of stacked devices, which may be connected with 3D wiring or metallization. Accordingly, high density circuit formation is enabled because devices are grown, or otherwise formed, vertically. Embodiments also include self-aligned contained cap layer etching techniques to greatly increase circuit routing density.

One advantage with techniques herein is enabling higher density circuits to be produced at reduced cost. The methods described herein provide an efficient 3D process flow that reduces masking steps (e.g., integrating the channel, S/D regions cut with one mask) with our invention with fewer process steps for fabricating the semiconductor device(s). Devices include vertical channel transistors with metal self-aligned to 3D source, gate, and drain on any semiconductor substrate for any number of vertical devices. Self-aligned dielectrics used herein as well as integrated hard mask etching enables the creation of openings for different metal contacts for drain, gate and source without any lithography.

Another advantage with techniques herein is enabling 3D horizontal device integration with metal self-aligned extensions for S/D EPI hookup. The methods described herein provide high-performance devices in both source, drain, and/or gate regions with the height based on the number of layers N. Further, the techniques herein enables connection between S/D of NMOS and PMOS for functioning as an inverter.

One embodiment described herein includes device (e.g., NMOS, PMOS, or others) fabrication techniques for 3D stacking with integrated channel, source, and drain regions cut with one mask using a 3D nanosheet formation side by side. Figures herein illustrate a 3D stack N=2 devices. Another embodiment includes device fabrication techniques for 3D stacking with integrated channel, source, and drain regions cut with one mask using a 3D nanosheet formation side by side, such as for fabricating a CMOS device. Figures show an example of N=2 devices. Yet another embodiment includes device fabrication techniques for 3D stacking with integrated channel, source, and drain regions cut with one mask using a 3D nanosheet formation side by side. In this embodiment, multiple devices (e.g., NMOS, PMOS, etc.) can be linked, hook up, or connected to function as an inverter.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections, and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

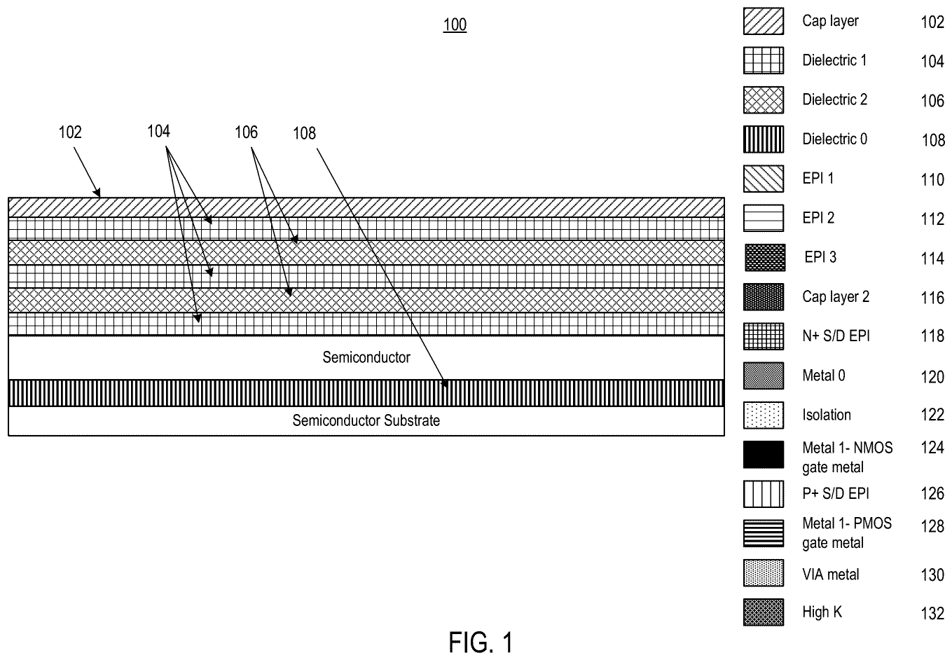

FIGS. 1-26 show various views of a first process flow to manufacture semiconductor devices with an integrated channel, source, and drain. Each of the FIGS. 1-26 generally refer to one or more process steps in a process flow, each of which are described in detail in connection with a respective Figure. For the purposes of simplicity and ease of visualization, some reference numbers may be omitted from some Figures.

FIG. 1 illustrates a cross-sectional view 100 of a semiconductor device in which various layers (e.g., sometimes referred to as blanket layers), including various materials (e.g., dielectric materials), are formed over at least one semiconductor substrate (or other types of substrate, such as a silicon substrate). The semiconductor substrate can be interposed by dielectric material 108 (e.g., shown in the legend as “Dielectric 0”). The dielectric materials discussed herein can be composed of any material with a relatively large dielectric constant and may include oxide materials. Certain dielectric materials can be a spacer for isolating or insulating materials. The dielectric material/layer may sometimes be referred to as an isolation material, insulation material, spacer material, among other similar terms.

The stack of layers includes alternating layers of the dielectric material 104 (e.g., shown in the legend as “Dielectric 1”) and dielectric material 106 (e.g., shown in the legend as “Dielectric 2”). The layers of the dielectric materials can be composed of or include similar materials/compositions or may be constructed from different dielectric materials. Different materials can be used, but subsequent etching is simplified with layers in the stack alternating between two materials. The layer stack can be formed on a substrate, which may be formed from silicon or other material. The formation of the various layers of the semiconductor device can include planarization of the layers, such as by cutting, ablation, chemical mechanical grinding or polishing (CMG/P), or other planarization techniques.

Subsequent to depositing the dielectric materials (e.g., alternating dielectric material 104 and dielectric material 106), a capping layer 102 or top layer (e.g., shown in the legend as “Cap layer 102”) can be deposited above the top surface of the stack of layers, such as above the dielectric material 104. The capping layer 102 can be relatively thicker or include a predefined thickness, and can be a hardmask material, such as TiN. The dielectric materials 104, 106 can be selected to have different etch resistivities. That is, a given dielectric material can be etched without etching other dielectric materials. The layers in the layer stack may be formed using any suitable material deposition technique, including atomic layer deposition (ALD), chemical vapor deposition (CVD), physical vapor deposition (PVD), plasma-enhanced CVD (PECVD), or epitaxial growth or deposition techniques.

In various arrangements, the layers can include similar thicknesses or different thicknesses according to the construction or configuration of the semiconductor device. Although five layers of the dielectric materials are shown, the stack of layers can include additional layers, such as additional dielectric materials. In some cases, there may be fewer layers in the stack of layers. In this example, the dielectric materials 104 can be used as spacers from channel to source or drain, such as described herein. In this step, the stack of layers can be referred to as a first stack including layers of dielectric materials 104 (e.g., first dielectric layers) and dielectric materials 106 (e.g., second dielectric layers) alternatively stacked on top of one another.

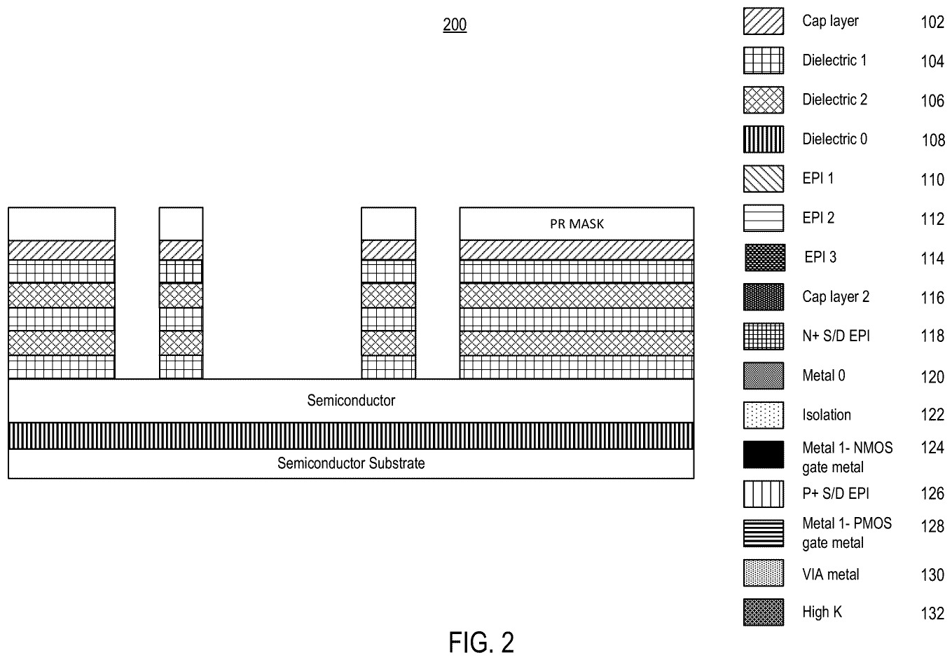

FIG. 2 illustrates a cross-sectional view 200 of the next stage in the process flow. At this stage in the process flow, an etch mask is formed and used to directionally etch openings through the layer stack until uncovering the substrate (e.g., semiconductor substrate, silicon substrate, or another underlying layer). Any suitable etching or material removal technique can be used, including but not limited to dry etching, wet etching, or plasma etching techniques, among others. The etch mask may be removed after the etching process (e.g., any etching process using the mask) is complete. The etching process may have an etch stop at the substrate. As shown, the etching process exposes the surface of the substrate, forming a vertical channel through the semiconductor device.

The etching process can be performed on various portions of the first stack. For example, three portions (e.g., first, second, and third portions) of the first stack can be etched using at least one suitable etching process. The first portion, the second portion, and the third portion may refer to any of the removed portions of the first stack, in this case. For instance, the middle portion may refer to the first portion, and the left or the right portions may refer to the first portion and the second portion, respectively, or vice versa. For example, the middle portion (e.g., first portion) may be used for or corresponds to a channel region. In another example, the left and right portions (e.g., second and third portions) may be used for or corresponds to metal regions (e.g., S/D regions). The various portions of the first stack are removed concurrently (e.g., at the same time). In some cases, the portions may be removed sequentially (e.g., one after another).

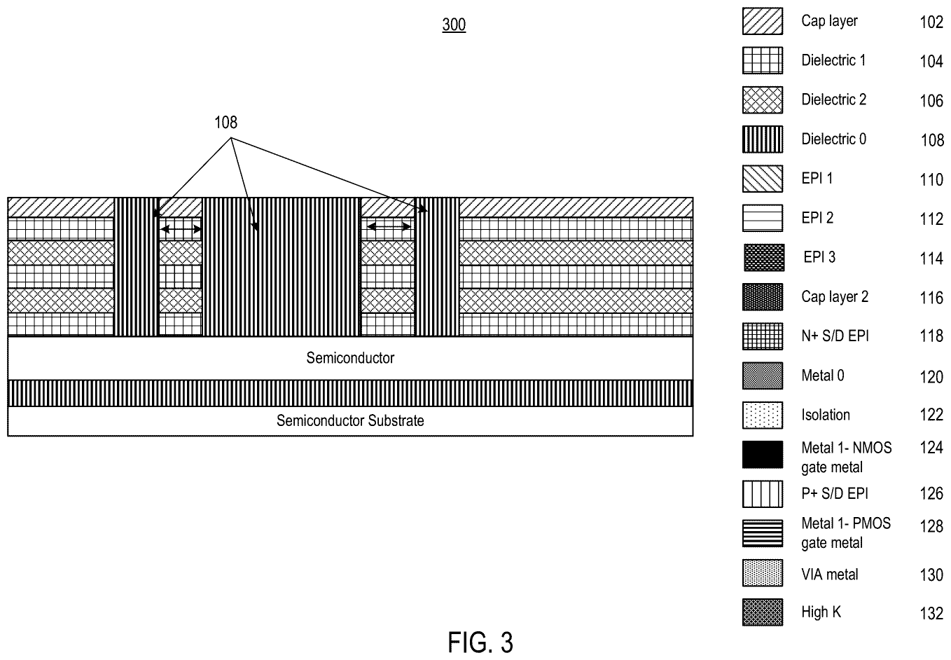

FIG. 3 illustrates a cross-sectional view 300 of the next stage in the process flow. After removing the portions of the first stack, the dielectric material 108 is filled to replace the removed portions. The dielectric material 108 is deposited using at least one suitable deposition technique. As shown, the three portions are filled with the dielectric material 108. For example, the respective removed portions are filled with respective dielectric structures (e.g., dielectric material 108), such as replacing the first portion with a first dielectric structure, the second portion with a second dielectric structure, and the third portion with a third dielectric structure. The distances, offsets, or spacings (e.g., spacer offset) between the first, second, and third portions of the first stack (e.g., between the filled dielectric material 108) are predefined/configured for the manufacturing process of the semiconductor device(s). Upon deposition of the dielectric material 108 (or other materials or structures discussed herein), there may be overburden or excess materials. Any such overburden may be etched or removed by a chemical-mechanical planarization (CMP) process, for example.

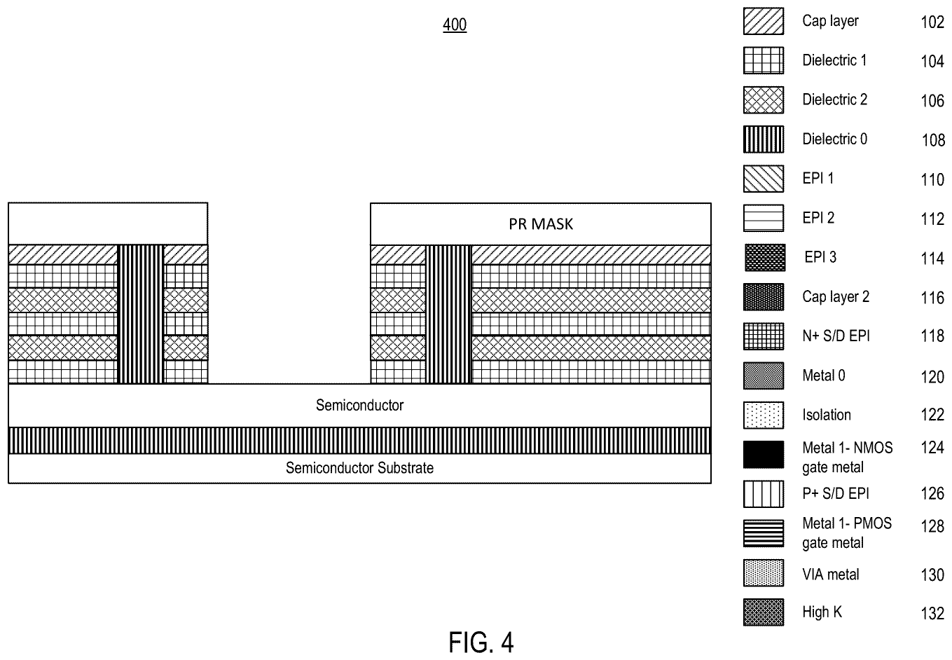

FIG. 4 illustrates a cross-sectional view 400 of the next stage in the process flow. At least one of the portions of the first stack (e.g., filled with the dielectric material 108) is removed. As shown, for example, the first portion of the first stack (e.g., the middle one of the dielectric material 108) is etched to expose the top surface of the underlying semiconductor substrate using at least one suitable etching technique.

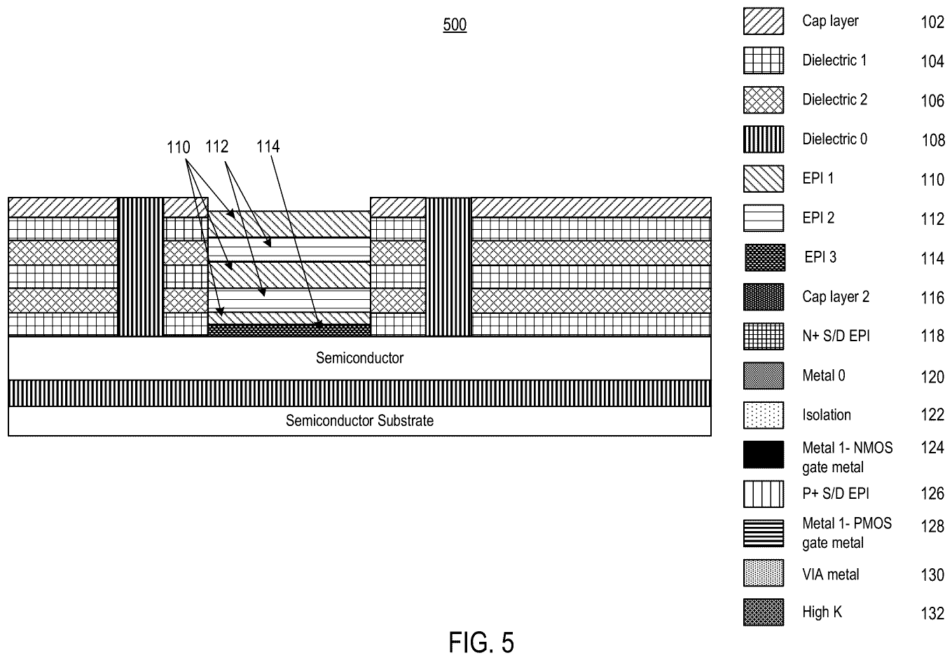

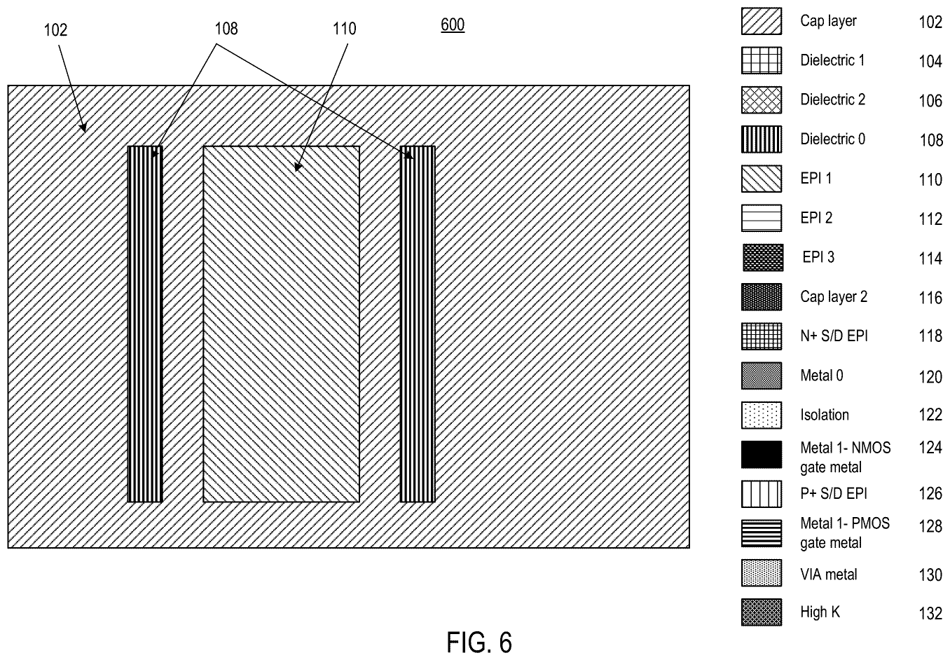

FIG. 5 illustrates a cross-sectional view 500 of the next stage in the process flow. FIG. 6 illustrates a top view 600 corresponding to the cross-sectional view 500. Vertical channel materials (e.g., the semiconductor materials 110, 112, 114, etc.) can then be grown epitaxially or formed with the uncovered substrate as a seed material, for example. The vertical channel materials can form a second stack as a replacement of the removed portion (e.g., the first portion) of the first stack. Each of the layers in the second stack can be epitaxially grown. To do so, in this stage in the process flow, a layer of a semiconductor material 114 (e.g., shown in the legend as “EPI 3,” sometimes referred to as a third semiconductor material/layer) can first be grown in the openings formed in the previous process step. The semiconductor material 114 may be any type of material that can be epitaxially grown on the substrate layer, such as SiGe. The semiconductor material 114 may be formed using any suitable material formation technique, including epitaxial growth. As discussed herein, the semiconductor material 114 can isolate the stack of layers (e.g., the second stack) from the substrate.

After forming the semiconductor material 114, the semiconductor material 110 (e.g., shown in the legend as “EPI 1,” sometimes referred to as a first semiconductor layer) is grown in the opening utilizing the semiconductor material 114 as a seed layer. The semiconductor material 110 can be formed to a predetermined height, for example, to just below the lower layer of the dielectric materials 106 in the first stack. In this step, the semiconductor material 110 can be a lower one of first (e.g., set of) semiconductor layers (e.g., lower first semiconductor layer).

The semiconductor material 112 (e.g., shown in the legend as “EPI 2”) is grown in the opening utilizing the semiconductor material 110 as a seed layer. The semiconductor material 112 can be formed to a predetermined height, for example, to just below the middle dielectric material 104 (e.g., middle one of the dielectric materials 104). The semiconductor material 112 can be a lower one of second (e.g., set of) semiconductor layers (e.g., lower second semiconductor layer). The semiconductor material 112 can include a similar height as the dielectric material 104.

After depositing the lower second semiconductor layer, another semiconductor material 110 is grown above the semiconductor material 112. At this process, the semiconductor material 110 can be referred to as a middle one of the first semiconductor layers (e.g., a middle first semiconductor layer). Subsequently, another semiconductor material 112 is grown above the middle first semiconductor layer. This semiconductor material 112 can be referred to as an upper one of the second semiconductor layers (e.g., an upper second semiconductor layer). After, another layer of the semiconductor material 110 is grown above the upper second semiconductor layer. This semiconductor material 110 can be referred to as an upper one of the first semiconductor layers (e.g., an upper first semiconductor layer). Hence, the second stack replacing the removed portion of the first stack can include the semiconductor materials 110, 112 that are alternately stacked on top of one another above the semiconductor material 114.

The one or more layers of the second stack can align with respective one or more layers of the first stack. For instance, one or more first semiconductor layers can align with at least one of the first dielectric layer(s) (e.g., the dielectric material 104). Further, one or more second semiconductor layers can align with at least one of the second dielectric layer(s) (e.g., dielectric material 106). In some implementations, the second stack (e.g., height) can vertically extend up to the capping layer 102 (or below the top surface of the capping layer 102).

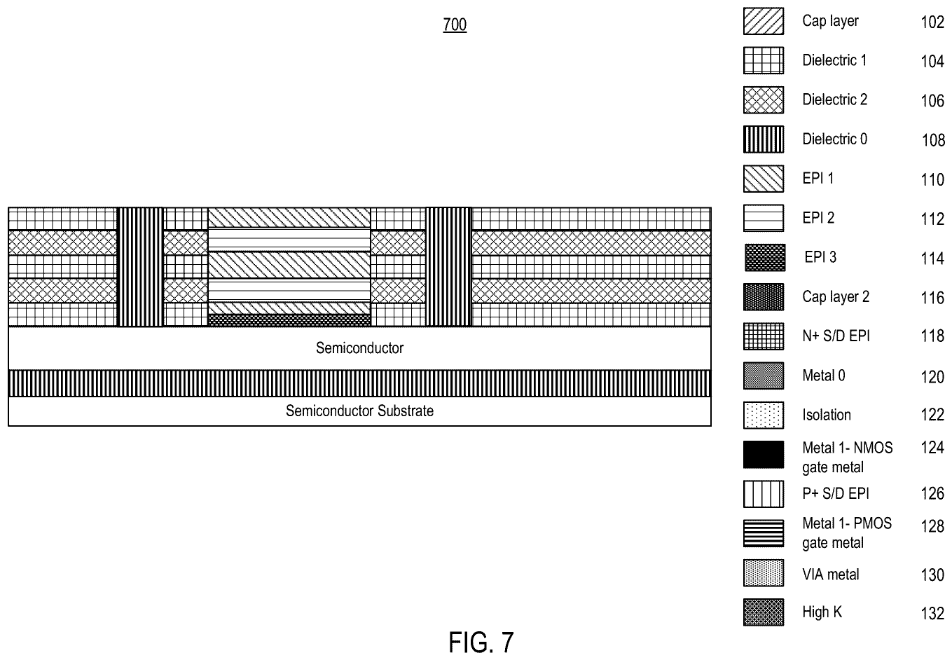

FIG. 7 illustrates a cross-sectional view 700 of the next stage in the process flow. After forming or growing the second stack including the semiconductor materials 110, 112, 114, the capping layer 102 is removed from the surfaces of the stacks (e.g., first and second stacks). For example, the stacks are planarized using at least one suitable etching technique to remove the capping layer 102.

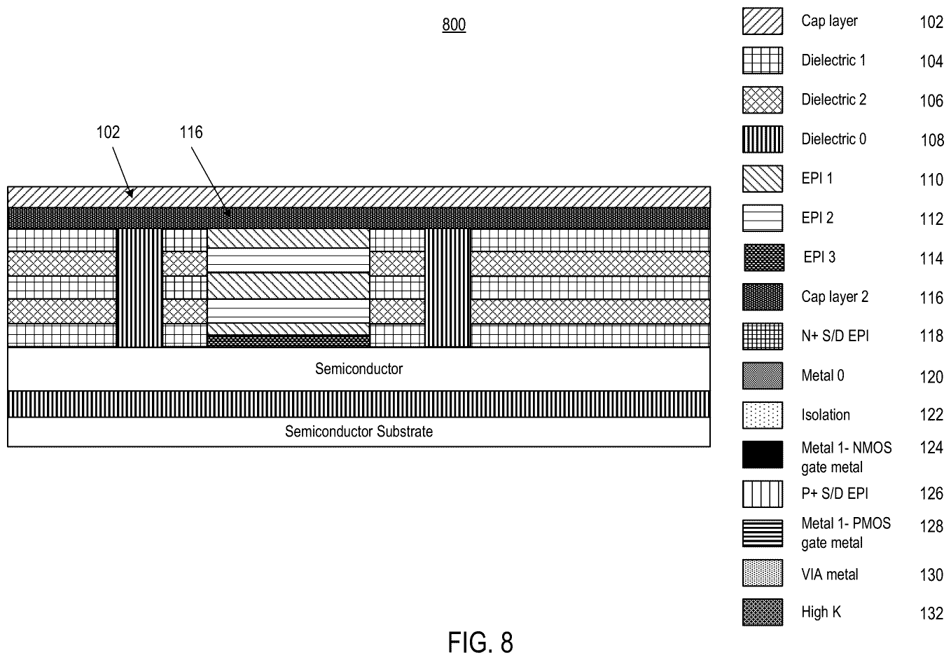

FIG. 8 illustrates a cross-sectional view 800 of the next stage in the process flow. After removing the capping layer 102 in the previous stage, one or more capping layers 102, 116 are deposited over the top surface of the stacks. For example, the capping layer 116 (e.g., shown in the legend as “Cap layer 2”) is deposited over the stacks, followed by the capping layer 102. In some arrangements, one capping layer or more than two capping layers may be deposited above the stacks.

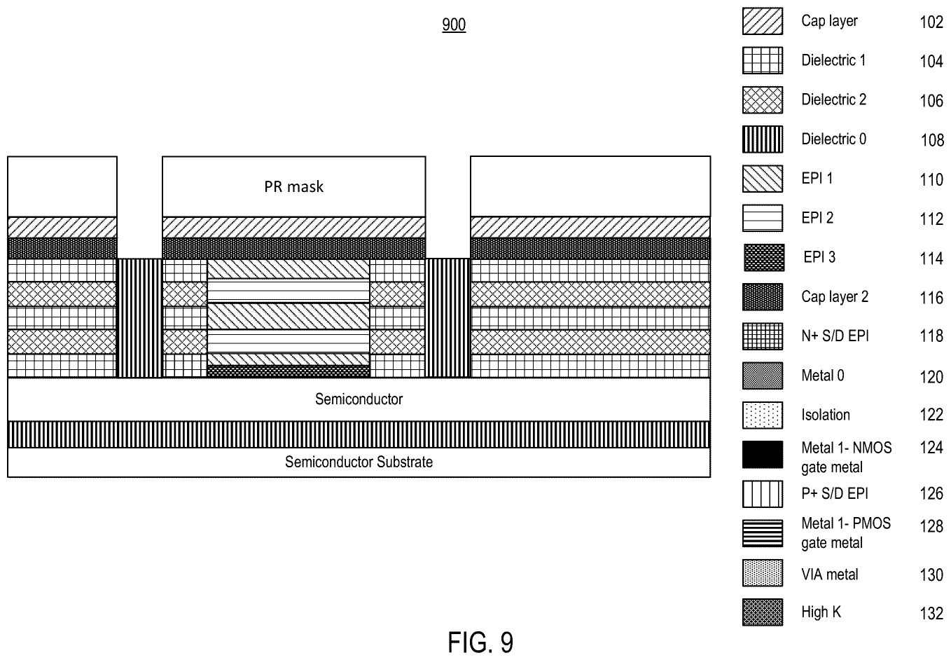

FIG. 9 illustrates a cross-sectional view 900 of the next stage in the process flow. A mask can be deposited above portions of the first stack (e.g., and the second stack). The mask can be patterned to have one or more openings (e.g., openings above the second and third portions of the first stack). As shown, for example, at least one suitable etching process is performed in the opening defined by the mask pattern. Portions of the capping layers 102, 116 are removed subsequent to the etching process to expose the top surfaces of the dielectric materials 108 deposited in the second and third portions of the first stack. The dielectric materials 108 can be accessed via the opening formed from this etching process, for example. The mask is removed following the removal of the portions of the capping layers 102, 116.

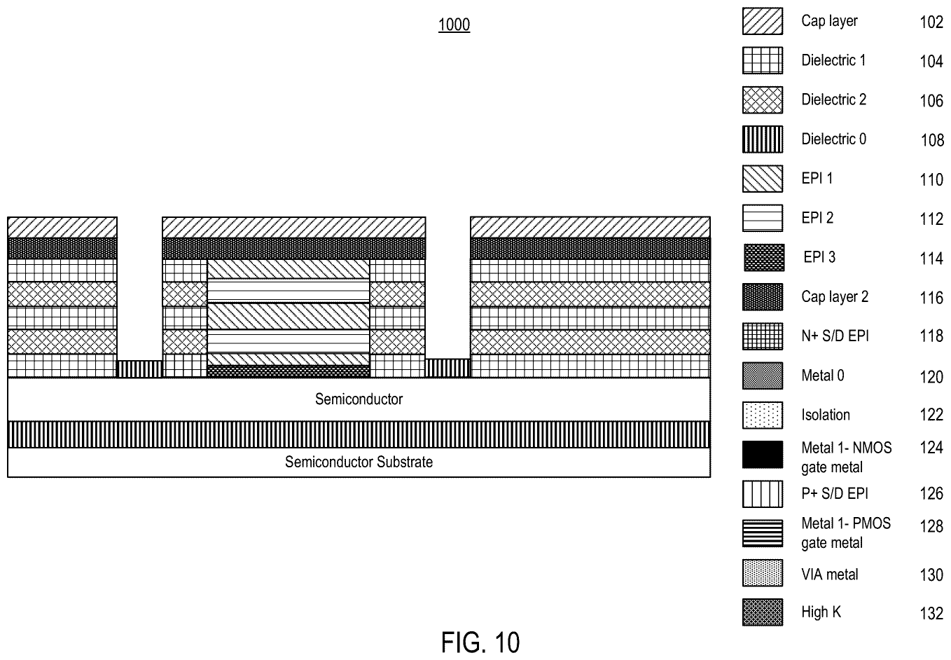

FIG. 10 illustrates a cross-sectional view 1000 of the next stage in the process flow. Via the opening of the capping layers 102, 116, the dielectric materials 108 are etched to reduce the height of the second and third dielectric structures. The dielectric materials 108 are etched by a predetermined vertical distance. As shown, the vertical distance of the dielectric materials 108 (e.g., second and third dielectric structures) is reduced at least to align with the top surface of the lower one of the dielectric materials 104 (or to align with a portion of the lower first dielectric layer), for example. The remaining dielectric materials 108 can be adjacent to the lower first dielectric layer. The (e.g., inner) sidewalls of the dielectric materials 104, 106 are exposed via the lateral opening formed by etching the dielectric material 108.

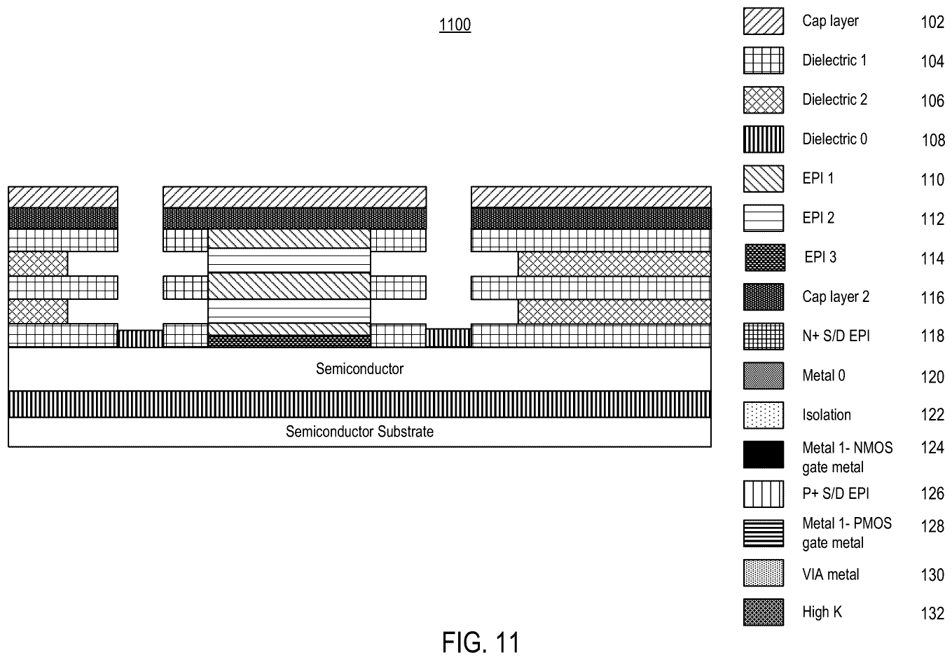

FIG. 11 illustrates a cross-sectional view 1100 of the next stage in the process flow. After forming the (e.g., vertical) channel openings at the second portion of the first stack, a portion of the dielectric material 106 can be horizontally etched. As shown, the dielectric material 106 (e.g., the upper and lower second dielectric layers) is selectively etched via the channel opening to form horizontal/lateral openings having a predetermined lateral distance/length. For example, the dielectric material 106 (e.g., upper and lower second dielectric layers) surrounding the sides of the semiconductor materials 112 (e.g., upper and lower second semiconductor layers) can be etched to expose the sidewalls or edges of the semiconductor materials 112. The horizontal etching process can be performed similarly to the third portion of the first stack, for example.

In some arrangements, the lateral etching operation can include two or more sub-operations. For example, a first sub-operation can include etching a first portion of the dielectric materials 106 adjacent to the second stack, and a second sub-operation can include etching a second portion of the dielectric materials 106 across the channel opening from the first portion of the dielectric materials 106. The lateral distance of the lateral etching operation can be predetermined up to the desired distance, for example. The recess etching laterally reduces the dimension of the layers of the semiconductor device. The reduction in lateral dimension can create a lateral channel opening for depositing additional materials or structures. These additional materials can be structured to (e.g., electrically) connect to the semiconductor materials 112 (e.g., materials to form the source or drain of the semiconductor device).

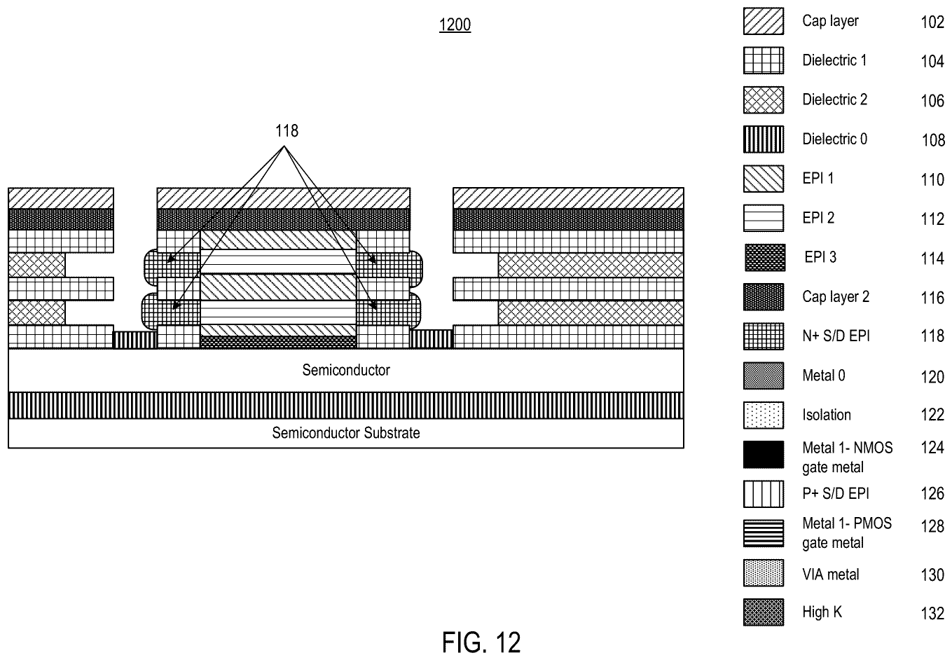

FIG. 12 illustrates a cross-sectional view 1200 of the next stage in the process flow. After the lateral etching operation, epitaxial materials 118 (e.g., shown in the legend as “N+ S/D EPI”, sometimes referred to as epitaxial structures or extensions) can be grown, deposited, or formed in the opening, such as the lateral opening exposing the sidewalls of the semiconductor material 112. Although the examples provided herein indicate an N-type semiconductor device, the EPI (e.g., epitaxial material 118) can be for a P-type semiconductor device, among others. Growing epitaxial material 118 can provide the S/D regions for the semiconductor device. The epitaxial material 118 can be formed through the removed second portion of the first stack to fill the lateral opening (e.g., grown from the Si channel or the dielectric material 104, not grown from dielectric material 106). In some cases, the epitaxial material 118 may extend or fill at least a portion of the vertical channel opening formed at the second portion of the first stack. The epitaxial material 118 can be in (e.g., electrical) contact with the semiconductor materials 112.

For example, a pair of the epitaxial material 118 (e.g., a pair of first epitaxial structures) can be formed in (e.g., electrical) contact with the lower one of the semiconductor materials 112. A pair of the epitaxial material 118 (e.g., a pair of second epitaxial structures) can be formed in (e.g., electrical) contact with the upper one of the semiconductor materials 112. Hence, the epitaxial materials 118 can be in (e.g., electrical) contact with the exposed sidewalls of the semiconductor materials 112. The epitaxial material 118 can be deposited into one or more portions of the opening via at least one suitable deposition technique. In some implementations, there may be a gap between the pair of first epitaxial structures and the pair of second epitaxial structures, as shown in this example (e.g., a separation between the EPI source and EPI drain).

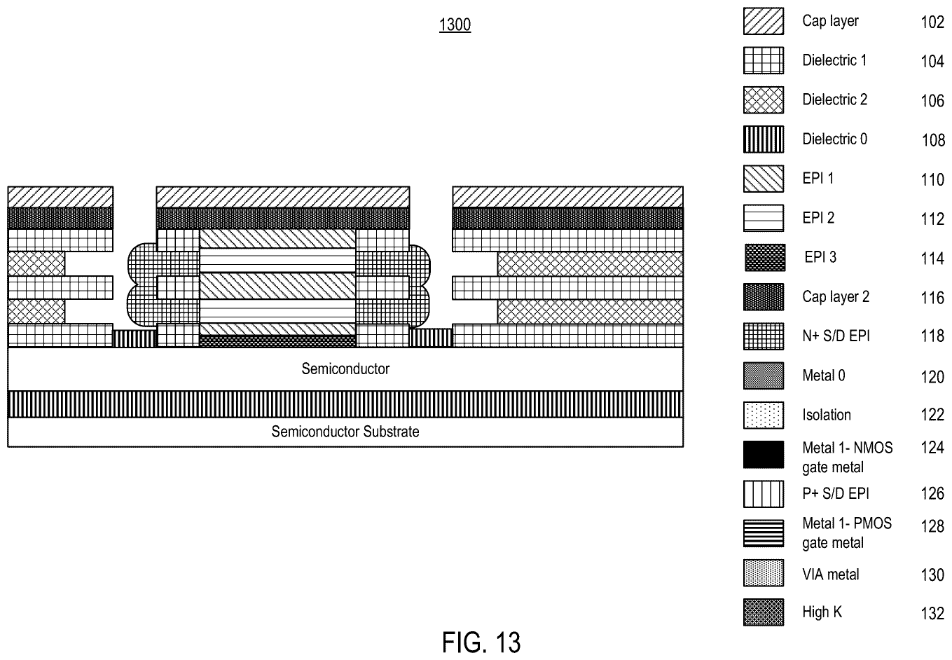

FIG. 13 illustrates a cross-sectional view 1300 of the next stage in the process flow. In some arrangements, the grown pairs of epitaxial materials 118 (e.g., the pair of first epitaxial structure and the pair of second epitaxial structure) are in (e.g., electrical) contact or shorted together. In this case, at least one suitable etching process may be performed to align with the capping layer(s) 102, 116 (or hard mask).

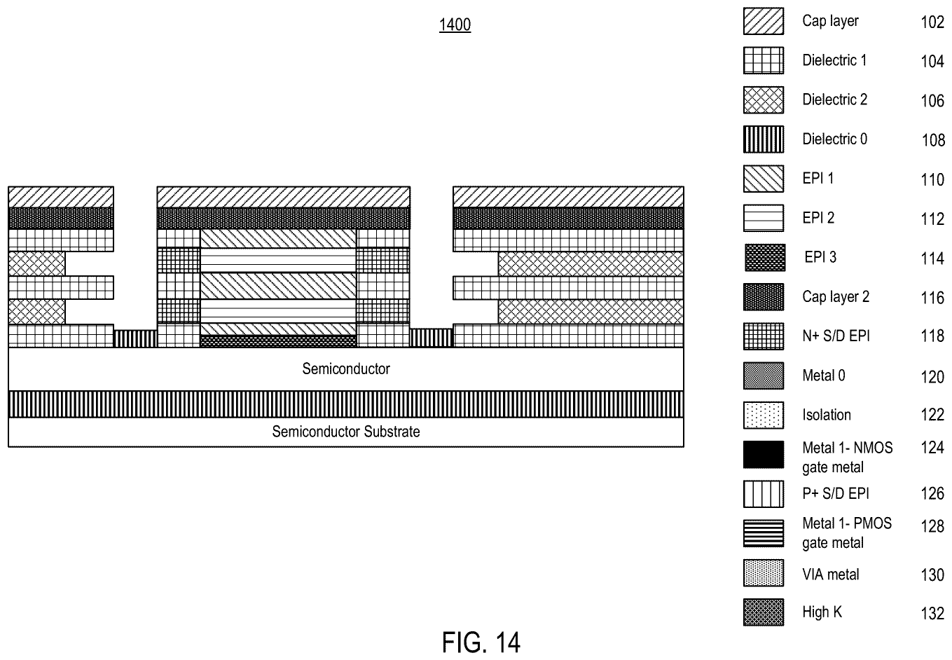

FIG. 14 illustrates a cross-sectional view 1400 of the next stage in the process flow. In various implementations, the epitaxial materials 118 (e.g., the pairs of first and second epitaxial structures) are etched from the channel opening to vertically align with the capping layers 102, 116 (e.g., align with the sides of the hard mask). For example, a portion of the epitaxial material 118 may be exposed to the vertical channel opening, or the respective pairs of epitaxial structures may be in contact with each other. As such, the epitaxial material 118 can be etched using at least one suitable etching technique via the vertical channel opening. By removing the epitaxial material 118 in the vertical channel opening, the exposed sidewalls of the epitaxial material 118 can be flushed with at least the exposed side walls of the dielectric material 104 (e.g., upper, middle, or lower first dielectric layers) adjacent to or in (e.g., electrical) connection with respective structures/materials/layers of the second stack. In some cases, the exposed sidewalls of the epitaxial material 118 can be aligned with the respective sidewall of the capping layer 102. Further, by removing the portion of the epitaxial material 118 (e.g., shown in cross-sectional view 1300), the pairs of epitaxial structures can be separated.

In some implementations, the epitaxial materials 118 (e.g., the pair of first epitaxial structures and the pair of second epitaxial structures) can have a thickness (e.g., first thickness) thinner than the thickness (e.g., second thickness) of each of the semiconductor material 112 (e.g., the second semiconductor layers). In some cases, the epitaxial materials 118 can have similar thickness as the semiconductor material 112.

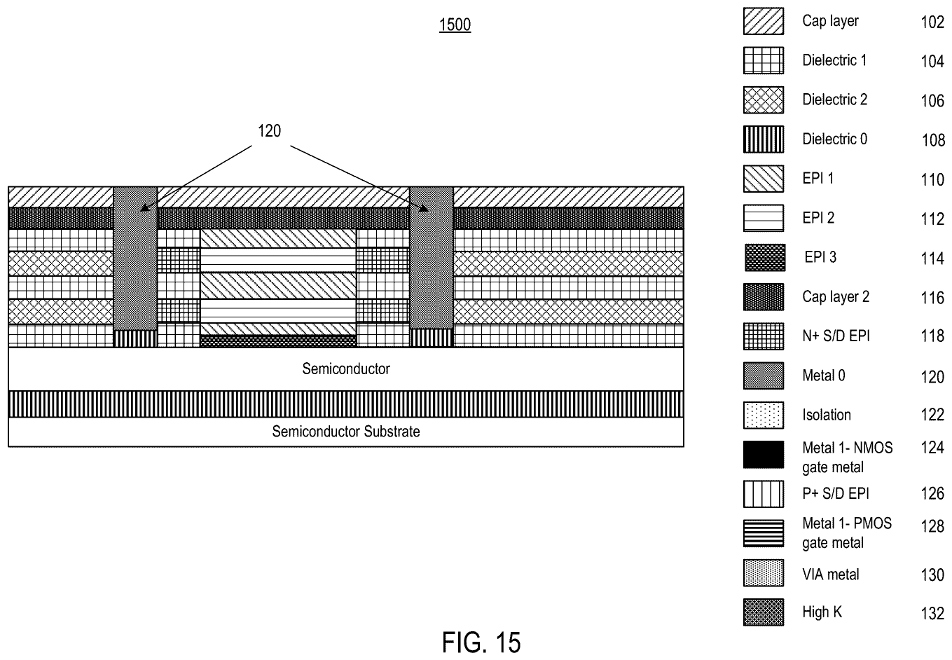

FIG. 15 illustrates a cross-sectional view 1500 of the next stage in the process flow. Subsequent to growing the epitaxial material 118 or etching the epitaxial material 118, metal materials 120 (e.g., shown in the legend as “Metal 0”, sometimes referred to as metal structures) can be deposited to fill the opening (e.g., remaining vertical openings) at the second portion and third portions of the first stack, for example. The metal material 120 can be disposed in the opening using at least one suitable deposition technique. The metal material 120 can be composed of any suitable conductive material, such as Cu, Al, W, Ti, TiN, Ta, TaN, or multiple layers or combinations thereof. The metal material 120 can fill the vertical openings (or lateral openings in some cases), such that the remaining opening or gap within the semiconductor device is filled with the metal material 120. The metal material 120 can extend vertically to align with the surface of the capping layer 102. In some cases, the metal material 120 can be etched to be flushed with the surface of the capping layer 102.

In some cases, prior to depositing the metal material 120, the dielectric material 106 is deposited in the remaining lateral openings adjacent to other portions of the dielectric materials 106. For instance, as shown in conjunction with FIG. 14, the lateral openings opposite the epitaxial material 118 are filled with the dielectric material 106. The deposited dielectric material 106 may be etched to be flushed with the inner sidewalls of the vertical channel opening.

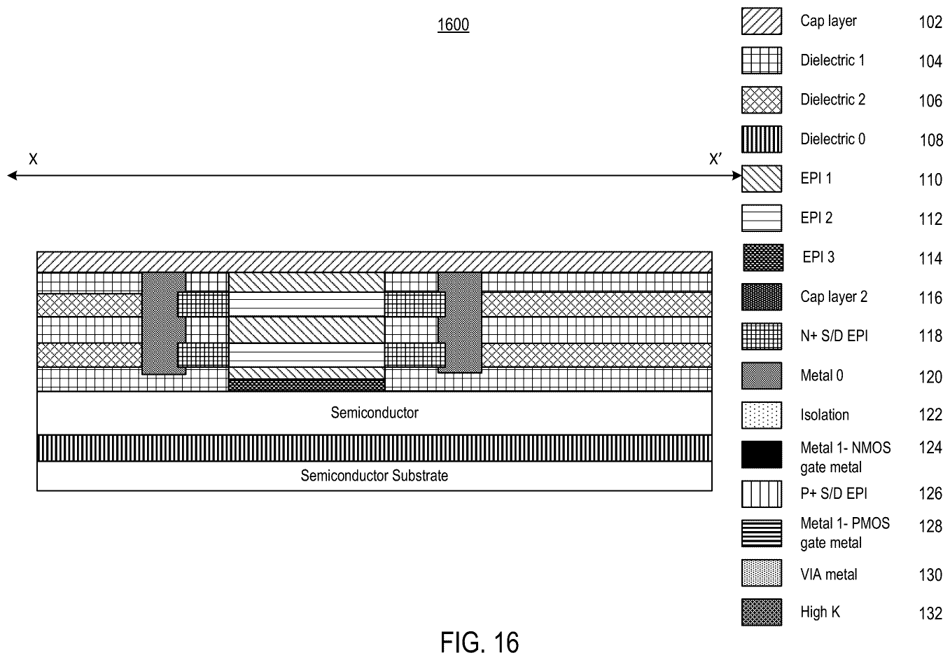

FIG. 16 illustrates a cross-sectional view 1600 of the next stage in the process flow. After depositing the metal material 120, the capping layers 102, 116 are removed via at least one suitable etching technique. The height of the metal material 120 is reduced via at least one suitable etching technique. For example, the height of the metal material 120 can be reduced down to the top surface of the upper first dielectric layer (e.g., the upper one of the dielectric materials 104 or dielectric layers). Subsequently, the capping layer 102 can be deposited above the stacks and the metal material 120. As shown, the capping layer 102 can be deposited above the semiconductor device.

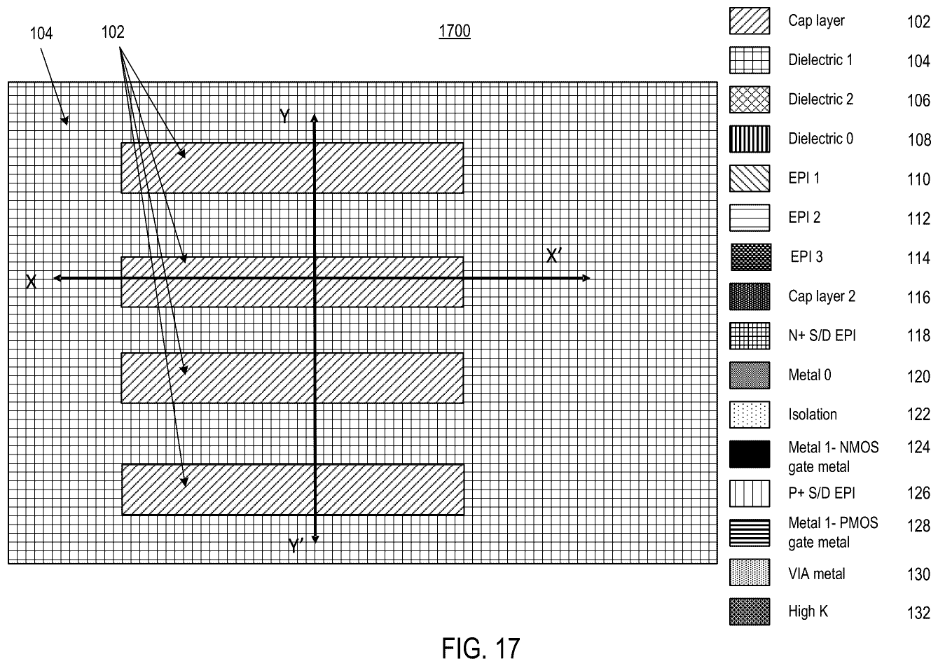

FIG. 17 illustrates a top view 1700 of the next stage in the process flow. After depositing the capping layer 102, the capping layer 102 can cover the top surfaces of the various structures discussed herein. In various implementations, the capping layer 102 can be etched using at least one suitable etching technique, such as a mask having a predetermined pattern. As shown, the capping layer 102 can be etched to define the y-dimension (e.g., the width) of individual 3D nanosheets (e.g., semiconductor devices). The y-dimension can be predetermined based on the configuration or the specification of the semiconductor device, for example. In some cases, the y-dimension of the individual nanosheets may be similar to one another. In some other cases, the y-dimension of at least one certain nanosheet may be different from at least one other nanosheet. Although four nanosheets are shown, additional nanosheets can be constructed or structured using similar operations described herein, for example. In various implementations, the capping layer 102 is deselected (e.g., not etched) over one or more regions, such as above at least one of the metal material 120 and the second stack, for example.

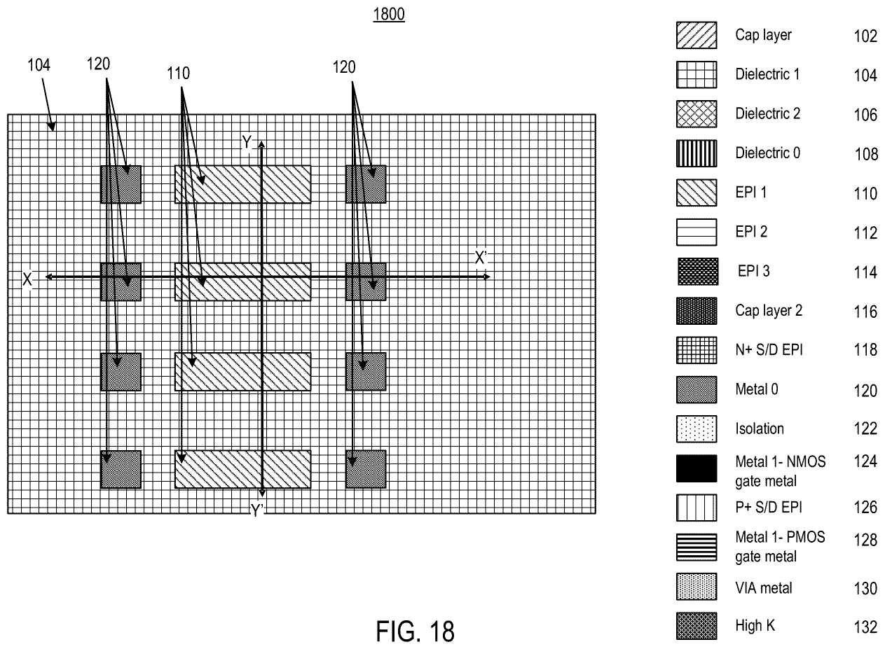

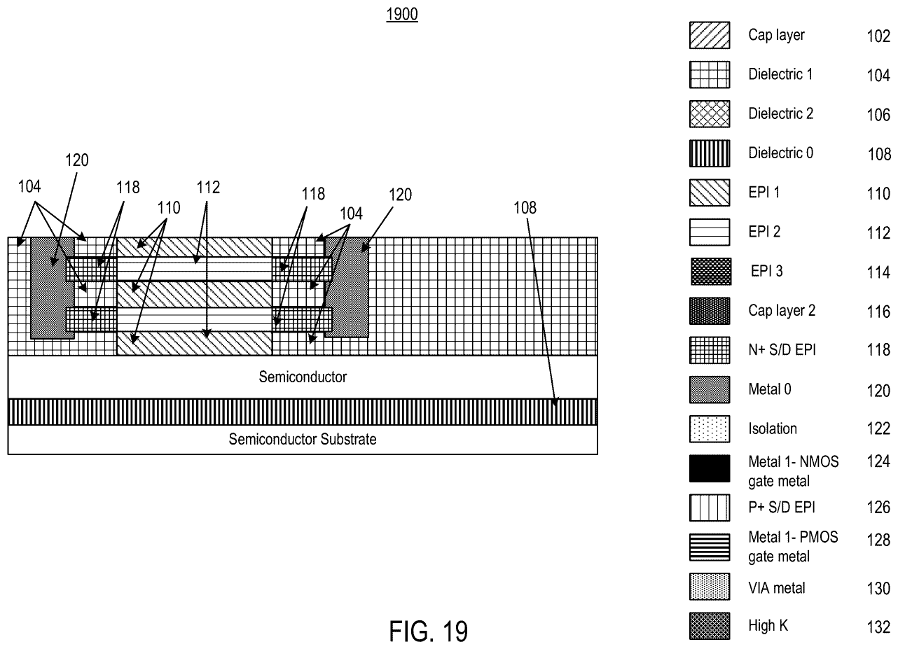

FIG. 18 illustrates a top view 1800 of the semiconductor device without the capping layer 102. FIG. 19 illustrates a cross-sectional view 1900 corresponding to the top view 1800 of FIG. 18. For purposes of providing illustrative examples, the top view 1800 and cross-sectional view 1900 show the current stage in the process flow of the semiconductor device without the capping layer 102.

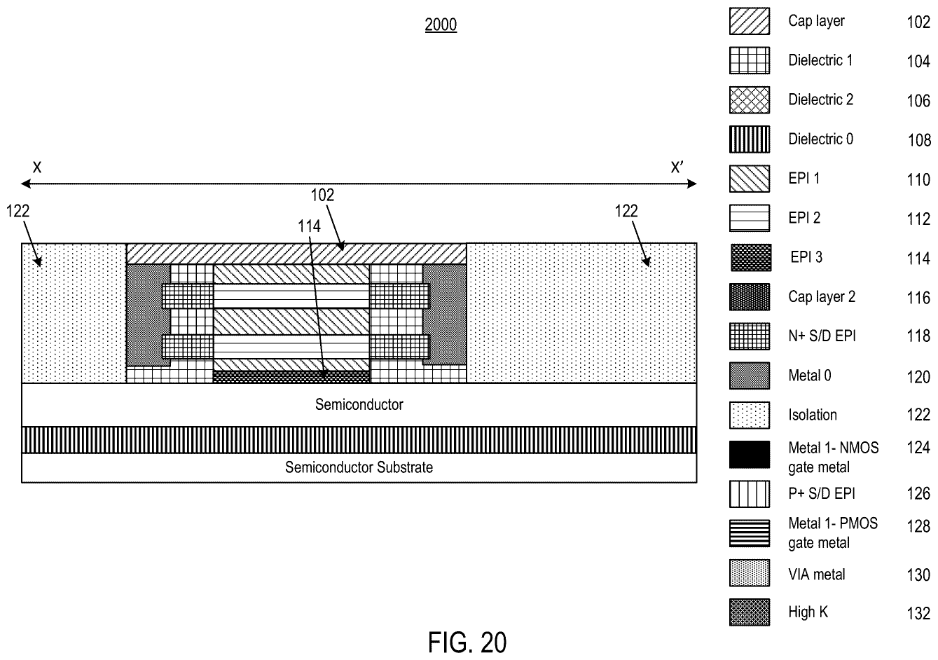

FIG. 20 illustrates a cross-sectional view 2000 of the next stage in the process flow. In some implementations, various portions of the first stack can be etched or removed, such as by using at least one suitable etching technique. For example, as shown, portions of the first stack surrounding or located at the sides of (e.g., adjacent to) the metal materials 120 can be removed. In this case, the removed portions of the first stack can extend laterally from the sidewall of the metal materials 120 (e.g., facing opposite from the second stack) onward.

After removing the portions of the first stack, an isolation material 122 can be deposited, such that the sidewalls of at least one of the metal materials 120, the lower dielectric material 104, or the capping layer 102 can be in contact with the isolation material 122. Deposition of the isolation material 122 can be performed using at least one suitable selective deposition technique. The isolation material 122 can be composed of any suitable material for isolating or insulating one material from another. In this case, the stacks or the various materials/structures (e.g., under the capping layer 102) can be isolated (e.g., laterally) from other materials by the isolation material 122. In some implementations, the isolation material 122 can be deposited (e.g., directly) above the surface of the semiconductor substrate (e.g., in contact with the semiconductor substrate). In some other implementations, the isolation material 122 can be deposited above at least a portion of the lower dielectric material 104 (e.g., the remaining portion of the lower first dielectric layer), for example.

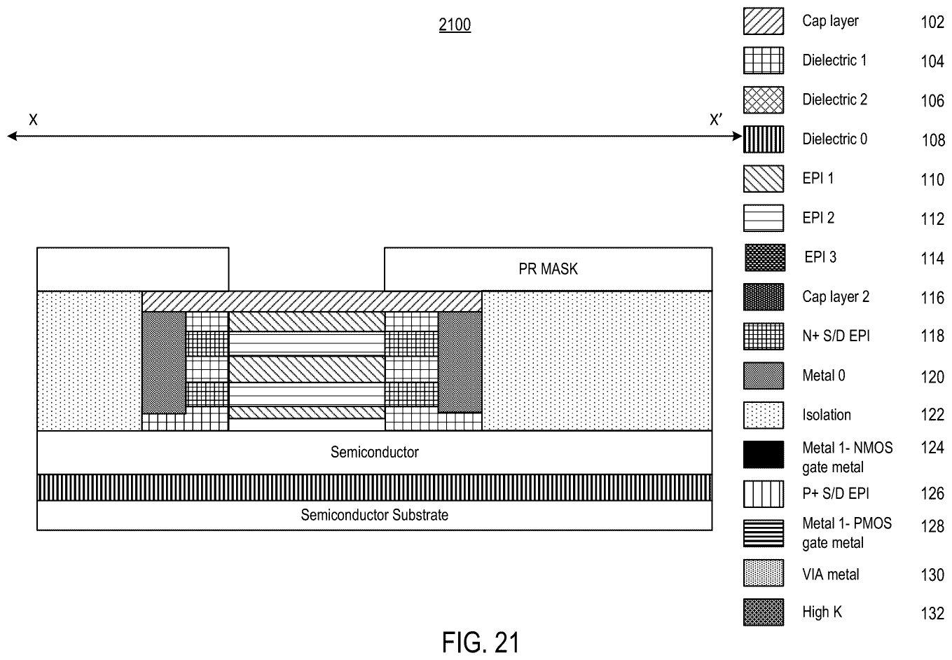

FIG. 21 illustrates a cross-sectional view 2100 of the next stage in the process flow. A mask can be deposited on or above the surface of the semiconductor device. The mask can include a predetermined/predefined pattern. For instance, the pattern may include an opening aligning with at least a portion of the second stack. The semiconductor material 114 can be removed or etched using at least one suitable etching technique, for instance, including the use of the mask. At this stage, as shown in FIG. 21, a gap between the lower semiconductor material 110 and the semiconductor substrate (e.g., below the second stack) is created at the removed semiconductor material 114 portion of the second stack.

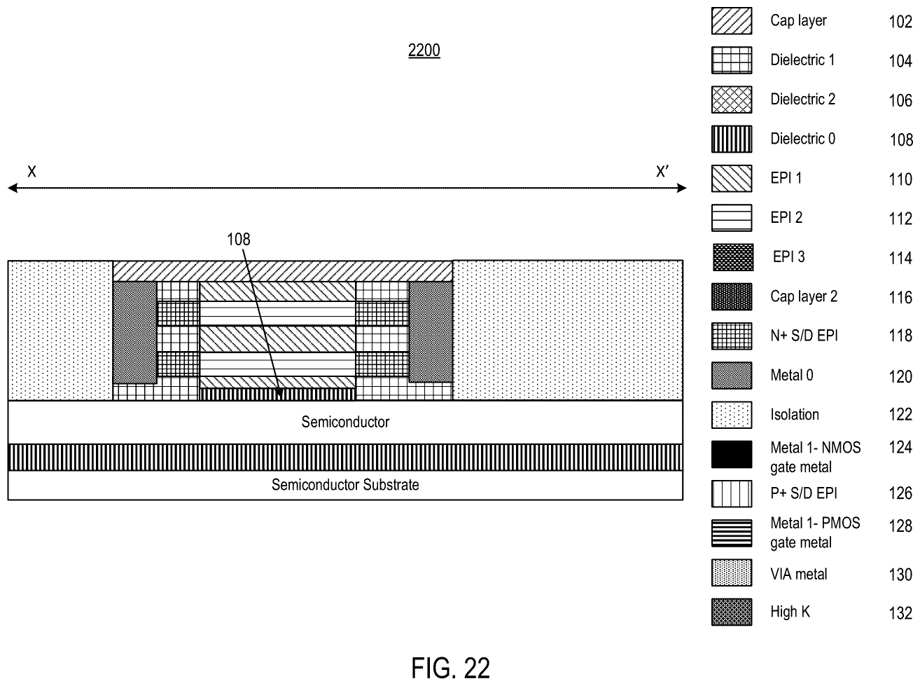

FIG. 22 illustrates a cross-sectional view 2200 of the next stage in the process flow. After removing the semiconductor material 114, the dielectric material 108 can be deposited to fill the gap (or opening) created by removing the semiconductor material 114. The dielectric material 108 can be deposited using at least one suitable deposition technique. Upon its deposition, the dielectric material 108 can be self-aligned with the capping layer 102. The dielectric material 108 isolates the second stack (e.g., including at least the semiconductor materials 110, 112, etc.) from the semiconductor substrate.

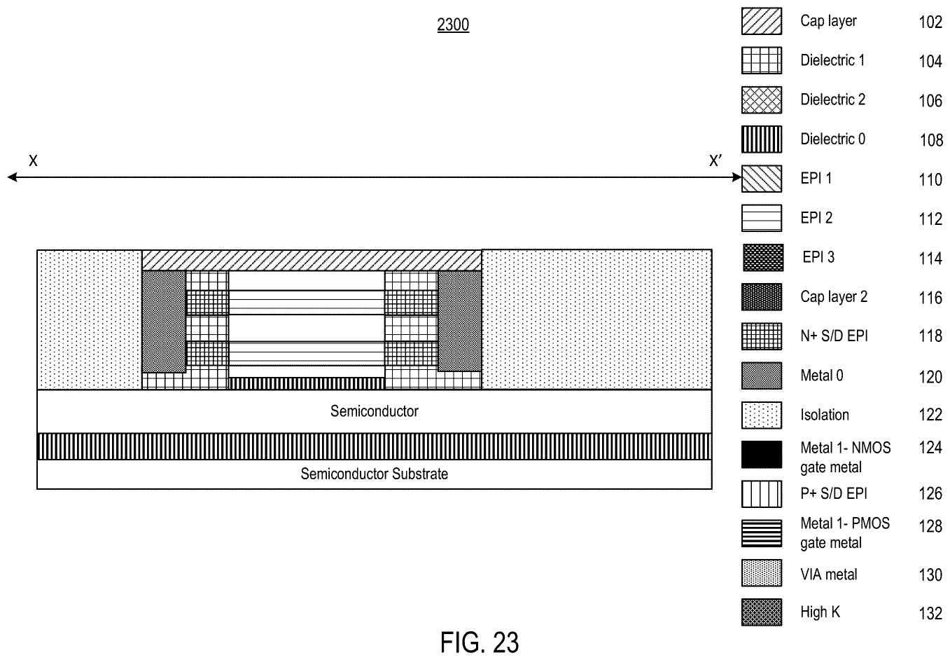

FIG. 23 illustrates a cross-sectional view 2300 of the next stage in the process flow. The semiconductor materials 110 (e.g., spacer layer) can be removed using at least a suitable etching technique. The semiconductor material 110 can assist with aligning the channel and S/D region with the gate structure, as described herein. In this case, removing the semiconductor materials 110 exposes the surfaces (e.g., top and/or bottom surfaces) of the semiconductor material 112.

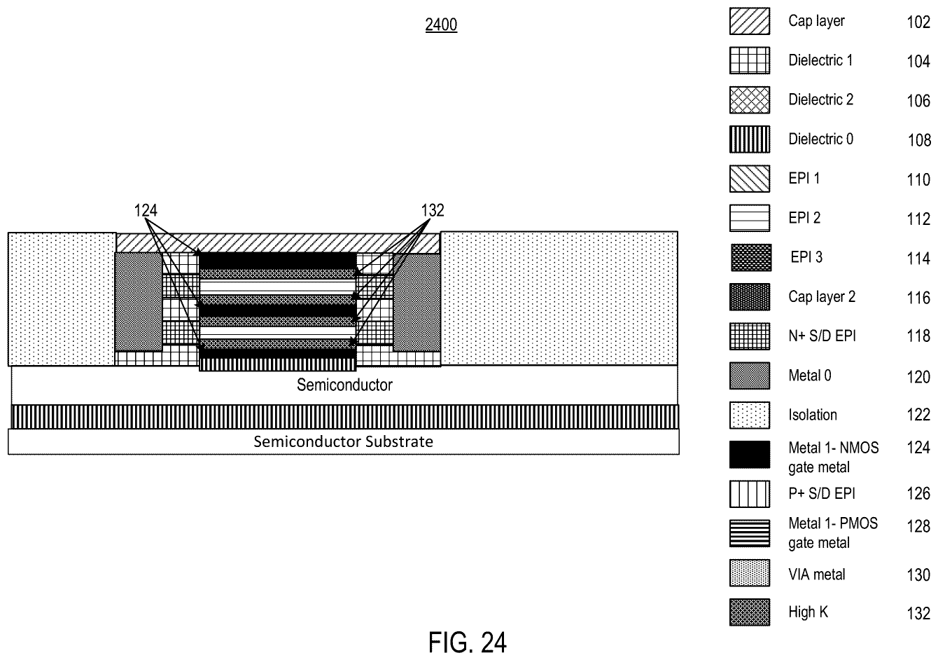

FIG. 24 illustrates a cross-sectional view 2400 of the next stage in the process flow. After removing the semiconductor materials 110, the removed portion of the second stack can be replaced or filled with metal material 124 (e.g., shown in the legend as “Metal 1—NMOS gate metal,” sometimes referred to as a gate metal material) and high-k dielectric material 132 (e.g., shown in the legend as “High K”). The metal material 124 and/or the high-k dielectric material 132 can be deposited using at least one suitable deposition technique. The metal material 124 can be composed of any types of conductive material, which may be similar to or different from the metal material 120. In some arrangements, the metal material 124 may be used for an NMOS gate, or other types of gate (e.g., according to the type of transistors).

The high-k dielectric material 132 can be in (e.g., vertical) contact with at least one of the metal material 124 and the semiconductor material 112. The metal material 124 can be in connection or contact with at least one of the high-k dielectric material 132, the capping layer 102 (e.g., in contact with the top most metal material 124), or the dielectric material 108. The high-k dielectric material 132 can be composed of any suitable materials having a high dielectric constant, such as compared to certain dielectric materials.

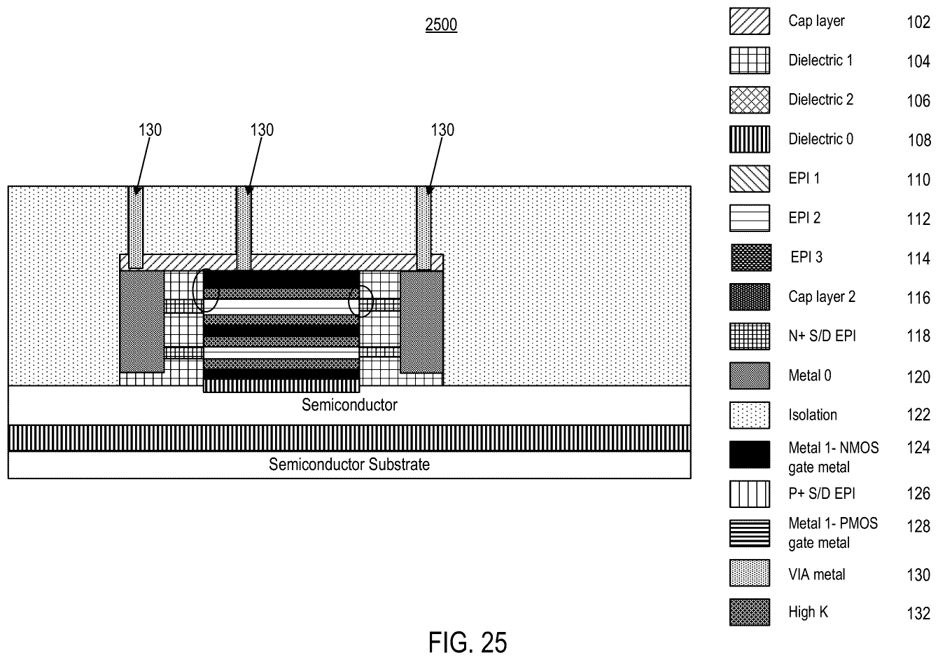

FIG. 25 illustrates a cross-sectional view 2500 of the next stage in the process flow. After depositing the metal material 124 and the high-k dielectric material 132, one or more via structures 130 (e.g., shown in the legend as “VIA metal,” sometimes referred to as a through channel or via material, etc.) can be formed. The via structure 130 can be composed of any suitable conductive material. As shown, the via structures 130 can be extended from the surface of the isolation material 122 to respective portions of the semiconductor device. For example, after the deposition of the metal material 124 and the high-k dielectric material 132, the isolation material 122 can be deposited above the semiconductor device using at least one suitable deposition technique. Various (e.g., vertical) openings (e.g., sometimes referred to as channels or channel openings) can be etched using at least one suitable etching technique. For instance, an opening may extend from the surface of the isolation material 122 to one of the metal materials 120 corresponding to one of the source or the drain of the semiconductor device. Similarly, another channel may extend from the surface of the isolation material 122 to another one of the metal materials 120 (e.g., on opposite side of the second stack) corresponding to the other one of the source or the drain of the semiconductor device. Yet another channel can be etched extending from the surface of the isolation material 122 to at least a portion of the metal material 124 (e.g., corresponding to a gate structure of the semiconductor device).

In further example, the one or more openings can be filled with the via structures 130. The via structures 130 can each (e.g., electrically) connect to at least one of the respective metal materials 120 and the metal material 124. The via structures 130 can route the respective materials to above the isolation material 122, such as for (e.g., electrical) connection with other materials or devices. Hence, the via structures 130 can provide connections from various devices or structures to the respective source (e.g., one of the sides of the metal material 120), drain (e.g., the other one of the sides of the metal material 120), and/or gate of the semiconductor device (e.g., the top/upper metal material 124).

As shown, the metal material 124 (e.g., gate structure) is self-aligned to (e.g., the start of) the semiconductor materials 112 (e.g., the channel extending between the pair(s) of epitaxial materials 118). For instance, the metal material 124 is vertically aligned with the semiconductor material 112 of the second stack. In some arrangements, the epitaxial materials 118 (e.g., the pairs of epitaxial structures for the S/D) can be thinner or include less vertical height compared to the semiconductor material 112 (e.g., channel between the source and drain). For example, as shown, the respective pairs of epitaxial materials 118 may be thinner compared to the semiconductor materials 112 interposed between the respective pair, such as to reduce or minimize capacitance coupled between the gate to drain or the gate to source.

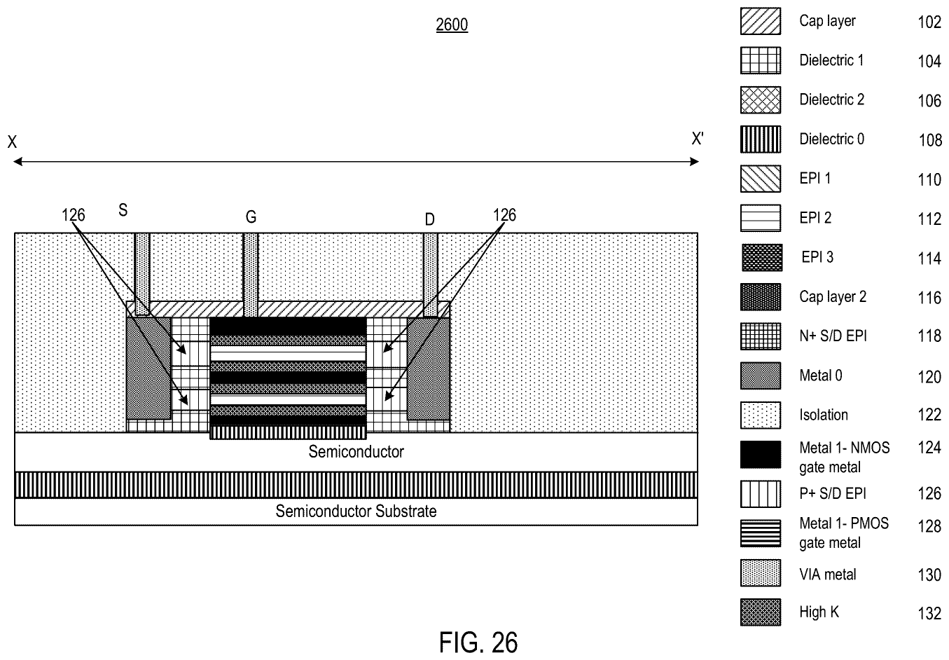

FIG. 26 illustrates a cross-sectional view 2600 of the next stage (or alternative stage) in the process flow. In some implementations, instead of the epitaxial material 118, epitaxial material 126 (e.g., shown in the legend as “P+ S/D EPI”) may be deposited and in contact with the semiconductor material 112, as shown. For example, referring back to FIG. 12, the epitaxial material 126 can be deposited instead of the epitaxial material 118. In some cases, the epitaxial material 126 is composed of at least one material suitable for P-type semiconductor device (e.g., PMOS), and the epitaxial material 118 is composed of at least one material suitable for N-type semiconductor device (e.g., NMOS), or vice versa.

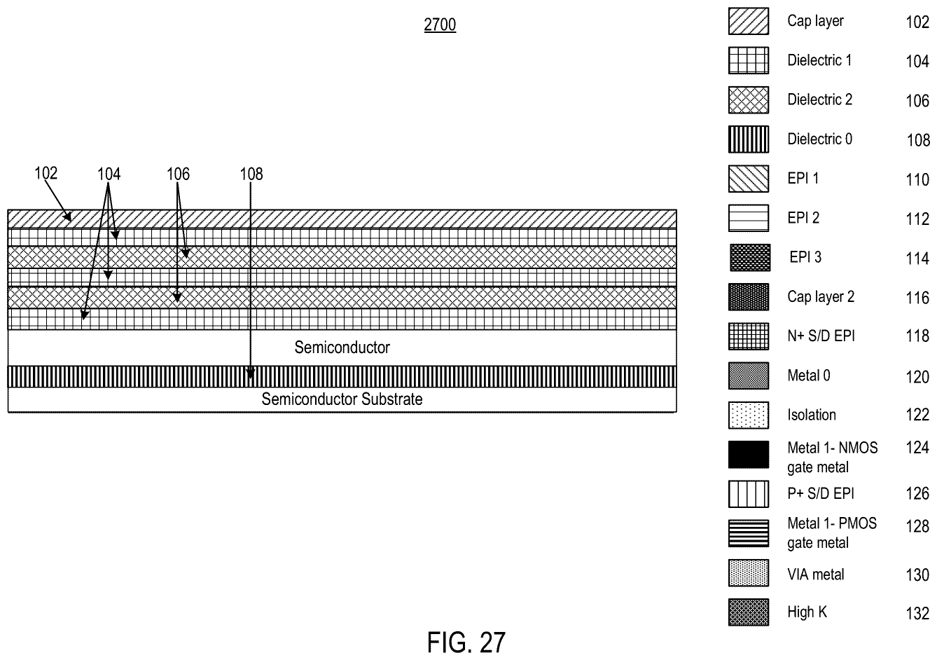

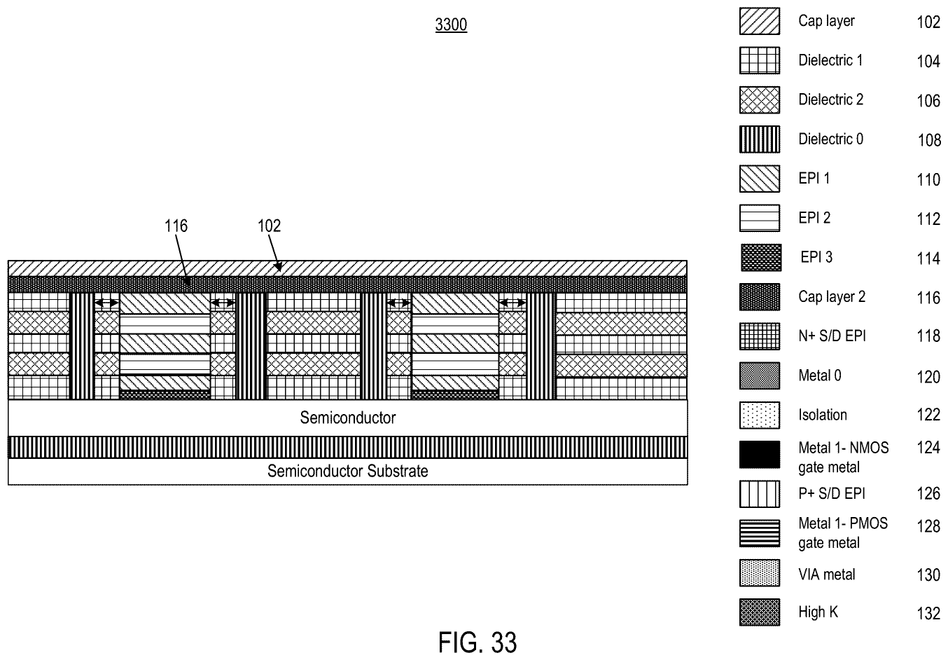

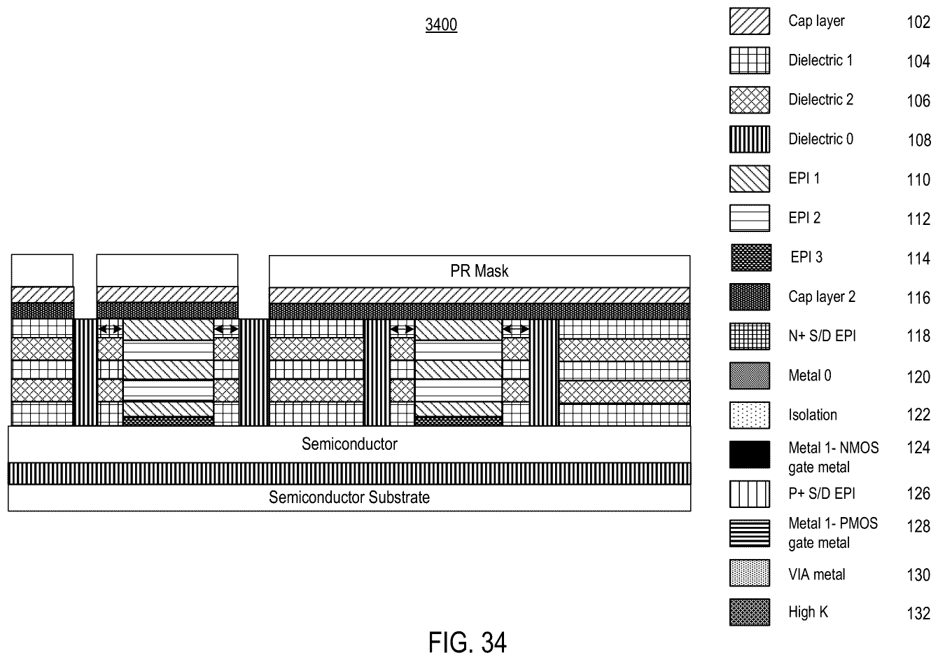

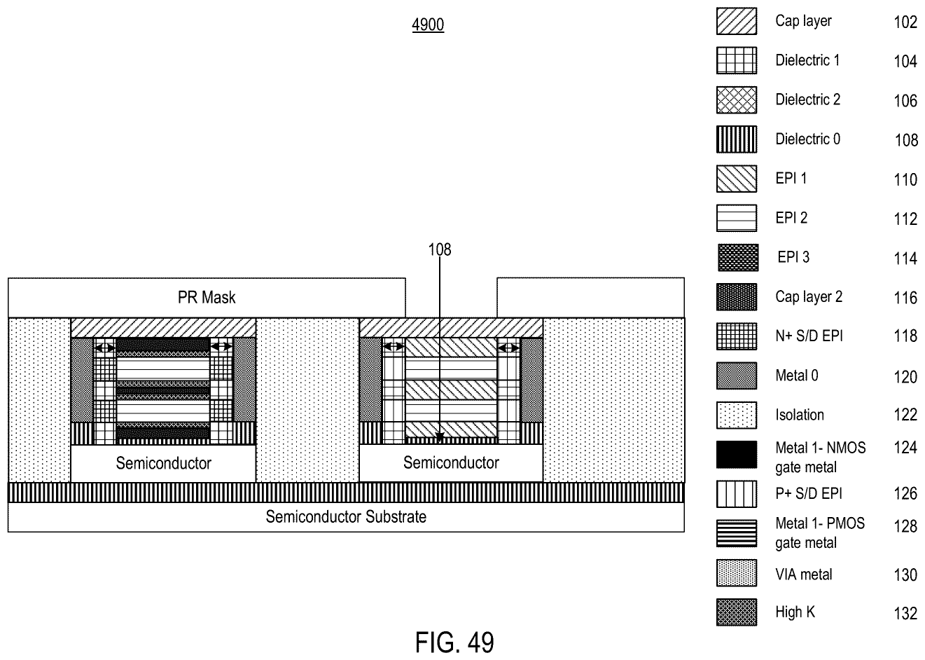

FIGS. 27-51 show various views 2700-5100 of a second process flow to manufacture semiconductor devices with integrated channel, source, and drain for CMOS. Each of FIGS. 27-51 generally refers to one or more process steps in a process flow, each of which are described in detail in connection with a respective Figure. For the purposes of simplicity and ease of visualization, some reference numbers may be omitted from some Figures. In FIGS. 27-51, an example process flow is described to manufacture a 3D stacking device with integrated channel, source, and drain cut with one mask using a 3D nanosheet formation side by side N=2 for CMOS.

The second process flow of FIGS. 27-51 can include operations, features, constructions, structures, or processes similar to one or more operations described in conjunction with at least one of FIGS. 1-26. For example, the operations of the second process flow can be performed using one or more similar techniques (e.g., etching, deposition, etc.) as at least FIGS. 27-51 of the first process flow.

FIG. 27 illustrates a cross-sectional view 2700 of a semiconductor device in which various layers, including various materials (e.g., dielectric materials), are formed over at least one semiconductor substrate. The operations (e.g., formation of the first stack) of FIG. 27 can be performed similar to the operations described in FIG. 1, for example. In this case, the first stack of the semiconductor device can include the capping layer 102 and dielectric materials 104, 106, 108. As shown, from the bottom to the top of the first stack above the semiconductor substrate, the first stack includes a lower one of the dielectric material 104, a dielectric material 106, a middle/center one of the dielectric material 104, a dielectric material 108, an upper one of the dielectric material 104, and the capping layer 102. In some cases, the capping layer 102 may not be a part of the first stack. Instead, the capping layer 102 can be another layer above the layers of the first stack. Hence, the first stack includes layers alternating between the dielectric materials 104 and both the dielectric materials 106, 108, in this case.

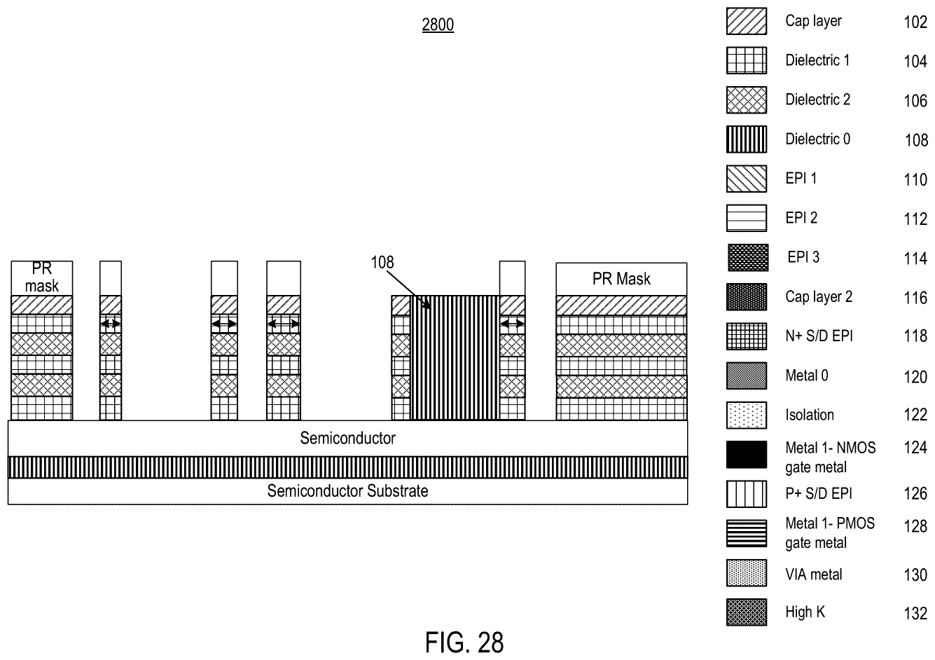

Subsequently, FIGS. 28-34 illustrate cross-sectional views 2800-3400 of the next stages in the process flow. The operations corresponding to FIGS. 28-34 can be similar to the operations described in conjunction with FIGS. 2-9. For example, referring to the cross-sectional view 2800, after forming the first stack, various portions of the first stack can be removed or etched. The removed portions of the first stack can correspond to a first semiconductor device (e.g., NMOS or others) and a second semiconductor device (e.g., PMOS or others). As shown, six portions are removed, where the respective portions correspond to source region, drain region, or channel region associated with the first semiconductor device or the second semiconductor device. For simplicity, the left portions (e.g., the first to third portions) are associated with the first semiconductor device, and the right portions (e.g., fourth to sixth portions) are associated with the second semiconductor device. These portions can be removed using at least one suitable etching technique, such as using the photoresist (PR) mask.

In various arrangements, certain operations performed for the first semiconductor device can be performed for the second semiconductor device. For instance, the first, second, and third portions of the first stack can be removed for the first semiconductor device. Similarly, the fourth, fifth, and sixth portions can be removed for the second semiconductor device. In some cases, the first and fourth portions can be associated with channel regions of the respective devices. The second, third, fifth, and sixth portions can be associated with the S/D regions of the respective devices. The first portion can include a similar width or different widths from the fourth portion. The second and third portions can include a similar width or different widths from the fifth and sixth portions. The surface of the semiconductor substrate can be exposed via the removed portions of the first stack.

As shown in cross-sectional view 2800, the dielectric material 108 can be deposited into at least one of the removed portions. In this case, the dielectric material 108 is deposited at a fourth portion (e.g., fourth dielectric structure) of the first stack. The dielectric material 108 can be deposited using at least one suitable deposition technique. Further, as shown in cross-sectional view 2900, the dielectric material 108 can be deposited to fill (or replace) the removed portions of the first stack. For instance, the first to fifth dielectric structures can be deposited at the corresponding first to fifth portions. Any overburden of the dielectric material 108 can be removed by the CMP process. For example, the CMP process can be performed and stopped on the capping layer 102. Therefore, the vertically filled dielectric material 108 can vertically extend from the surface of the semiconductor substrate to (e.g., align with) the surface of the capping layer 102.

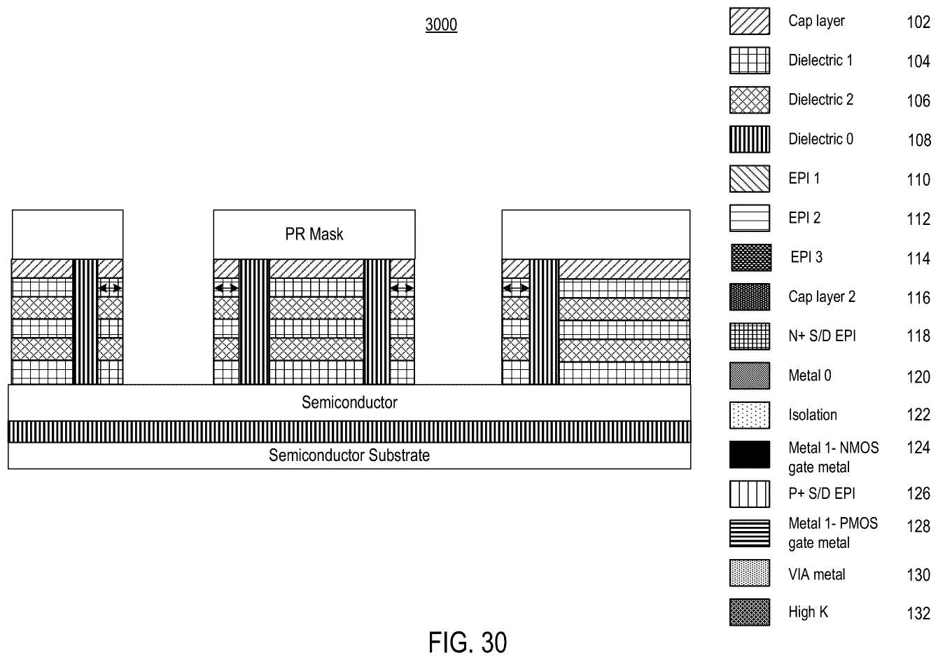

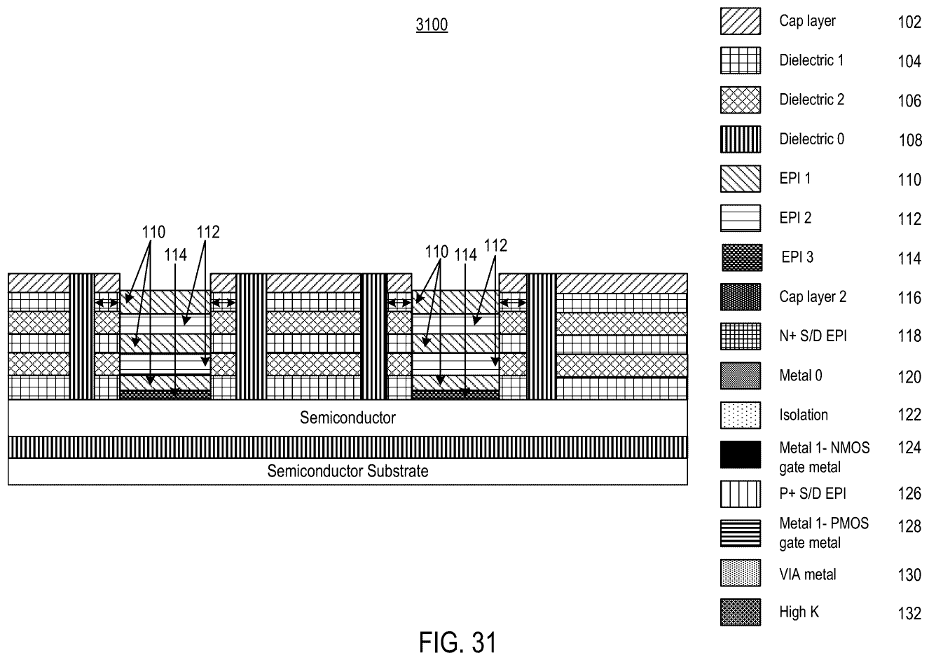

Referring to FIG. 30, the dielectric material 108 at the first portion and the fourth portion can be etched or removed. In this case, the removal of the dielectric material 108 for the channel regions can be performed similarly to the operation of FIG. 4, for example. Referring to FIG. 31, at least one second stack can be formed or grown using at least one suitable material formation technique, including epitaxial growth. The formation of the second stack can be performed for both the first semiconductor device and the second semiconductor device. In some cases, the additional stack for the first semiconductor device may be referred to as a second stack and the additional stack for the second semiconductor device may be referred to as a third stack. The second stack and the third stack can include at least one of the semiconductor materials 110, 112, 114. The semiconductor material 114 can be formed above the surface of the semiconductor substrate to isolate the semiconductor materials 110, 112 from the semiconductor substrate. The semiconductor material 114 may or may not be a part of the second stack. The semiconductor materials 110, 112 can be alternatively stacked on top of one another. For instance, from the semiconductor material 114 to the top of the respective second and third stacks, the stacks include a lower one of the semiconductor materials 110, a lower one of the semiconductor materials 112, a center/middle one of the semiconductor materials 110, an upper one of the semiconductor materials 112, and an upper one of the semiconductor material 110. The semiconductor materials 110 can laterally align, in part, with the dielectric materials 104 of the first stack. The lower one of the semiconductor materials 112 (e.g., lower second semiconductor layer) can laterally align, in part, with the dielectric material 106. The upper one of the semiconductor materials 112 (e.g., upper second semiconductor layer) can laterally align, in part, with the upper one of the dielectric materials 106.

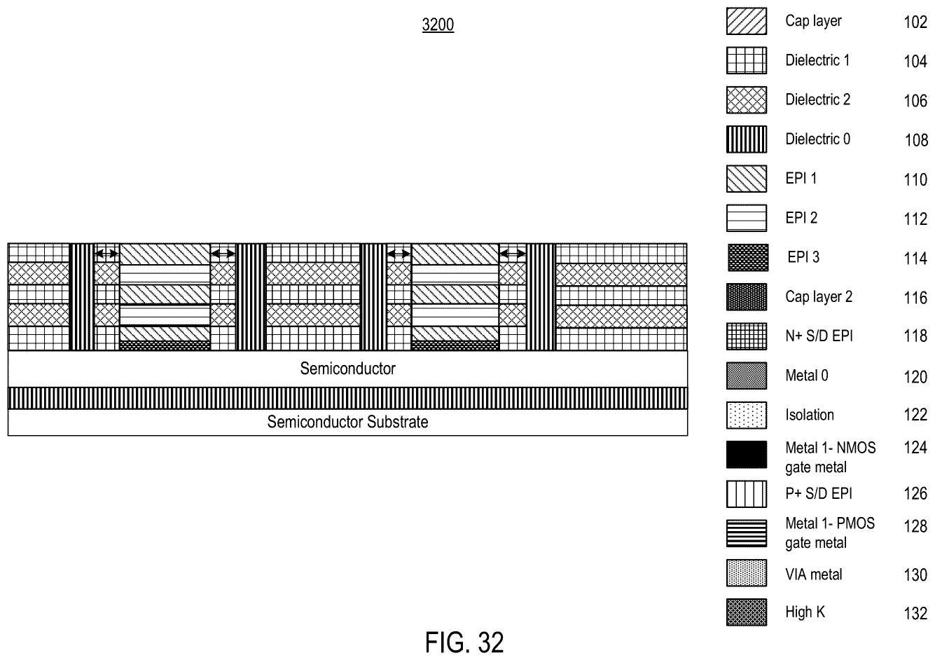

Referring to the cross-sectional view 3200, the operation performed can be similar to the operation of FIG. 7. For example, at least one suitable etching technique or CMP process can be performed to remove the capping layer 102 and a portion of the dielectric materials 108. As shown in FIG. 32, the materials or structures can be removed down to the surface of the upper one of the dielectric material 104 or the top surface of the second stack.

Referring to the cross-sectional view 3300, the operation performed can be similar to the operation of FIG. 8. For example, after removing the capping layer 102, the capping layer 116 (e.g., a second capping layer) is deposited above the devices. The capping layer 102 is deposited above the capping layer 116. The deposition of the capping layers 102, 116 is performed using at least one suitable deposition technique.

Referring to the cross-sectional view 3400, the operation performed can be similar to the operation of FIG. 9. For example, portions of the capping layers 102, 116 are etched. The etched portions vertically align with the second and third dielectric structures (e.g., S/D portions of the dielectric materials 108 for the first semiconductor device). As shown, the top surface of the dielectric materials 108 (e.g., the second and third dielectric structures) can be exposed via the removed portions of the capping layers 102, 116.

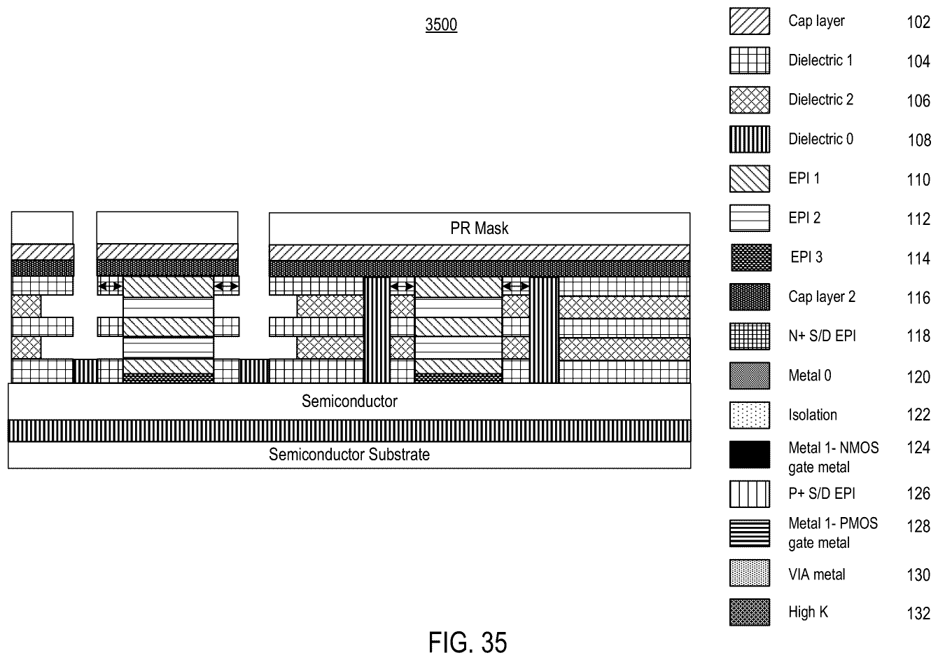

FIG. 35 illustrates a cross-sectional view 3500 of the next stage in the process flow. The operation of FIG. 35 can, at least in part, be performed similarly to the operation of at least FIGS. 10-11. For example, via the opening of the capping layers 102, 116, the dielectric materials 108 at the second and third portions of the first stack are etched to reduce the height of the second and third dielectric structures. The dielectric materials 108 are etched by a predetermined vertical distance, such as reduced at least to align with the top surface of the lower one of the dielectric materials 104, for example. Subsequent to etching the dielectric materials 108, the side surfaces or side walls of at least the dielectric materials 106 can be exposed through the vertical opening formed from etching the dielectric material 108. Via the formed openings, a portion of the dielectric material 106 can be horizontally etched. As shown, the dielectric material 106 (e.g., the upper and lower second dielectric layers) is selectively etched via the channel opening to form horizontal/lateral openings having a predetermined lateral distance/length. As shown, etching the dielectric material 106 exposes the sidewalls or edges of the semiconductor materials 112 (e.g., the second semiconductor layers of the first device).

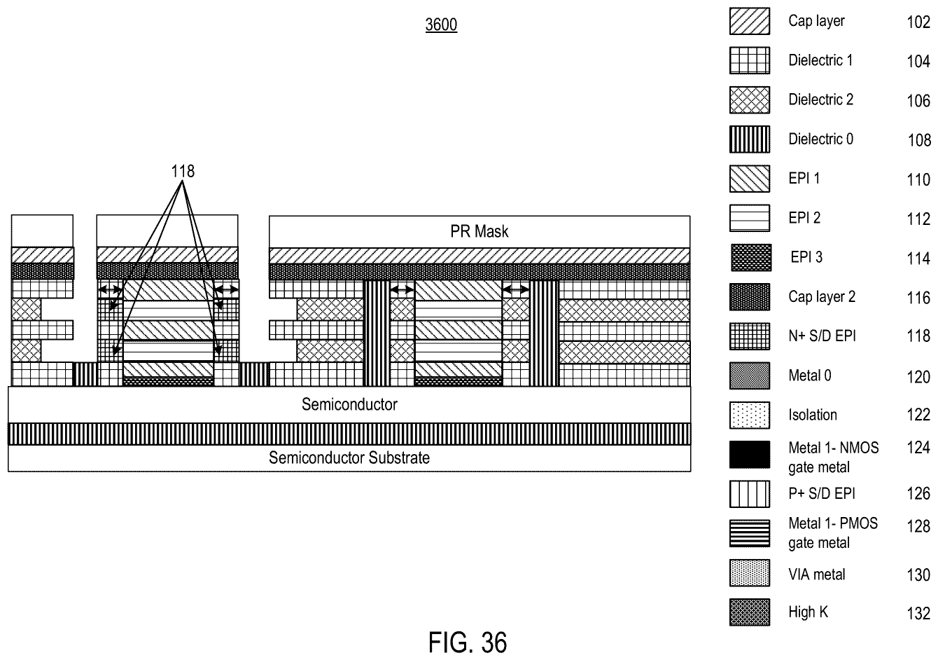

FIG. 36 illustrates a cross-sectional view 3600 of the next stage in the process flow. After forming the lateral opening to expose the sidewalls of the semiconductor materials 112, the epitaxial materials 118 (e.g., first and second epitaxial structures) can be grown using the dielectric material 104 as the seed layer. A pair of first epitaxial structures can be in contact with the exposed sidewalls of the lower one of the semiconductor material 112. A pair of second epitaxial structures can be in contact with the exposed sidewalls of the upper one of the semiconductor material 112. In some cases, the epitaxial materials 118 can be vertically aligned with the capping layers 102, 116 above the second stack by etching the epitaxial materials 118 in the vertical channel opening. As shown, the exposed sidewalls of the epitaxial materials 118 can be flushed with at least the exposed sidewall of the dielectric material 104 above the respective epitaxial materials 118. In some other cases, the epitaxial materials 118 may be grown into a portion of the vertical channel opening, such as shown in FIG. 13, for example. The operation of FIG. 35 can, at least in part, be performed similarly to the operation of at least one of FIGS. 12-14, for example. In this example, the epitaxial material 118 may be formed of materials suitable for an NMOS device.

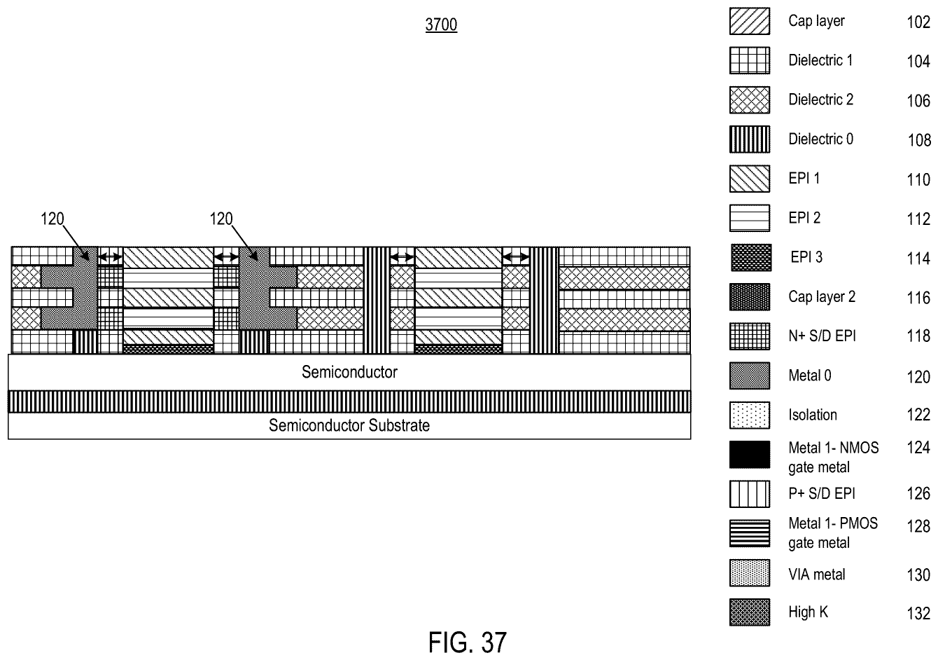

FIG. 37 illustrates a cross-sectional view 3700 of the next stage in the process flow. After forming the epitaxial materials 118, a pair of metal materials 120 (e.g., metal structures) are deposited into the opening (e.g., remaining openings). The metal materials 120 can be deposited using at least one suitable deposition technique. The metal materials 120 can be in (e.g., electrical) contact with the pairs of epitaxial structures (e.g., epitaxial materials 118). The metal materials 120. The operation for depositing the metal material 120 can be performed similarly to the operation described in FIG. 15, for example.

Subsequently, the capping layers 102, 116 are removed. The removal of the capping layers 102, 116 can be performed using at least one suitable etching technique, such as the CMP process. Removing the capping layers 102, 116 can remove a portion of the metal materials 120. In some cases, the metal material 120 is etched prior to removal of the capping layers 102, 116. As shown, the metal material 120 may be etched, such that the top surface of the metal material 120 laterally align with the top of the stacks (e.g., upper dielectric structures and upper semiconductor structures). The operation for removing the capping layers 102, 116, among other materials, can be performed similarly to the operation described in FIG. 16.

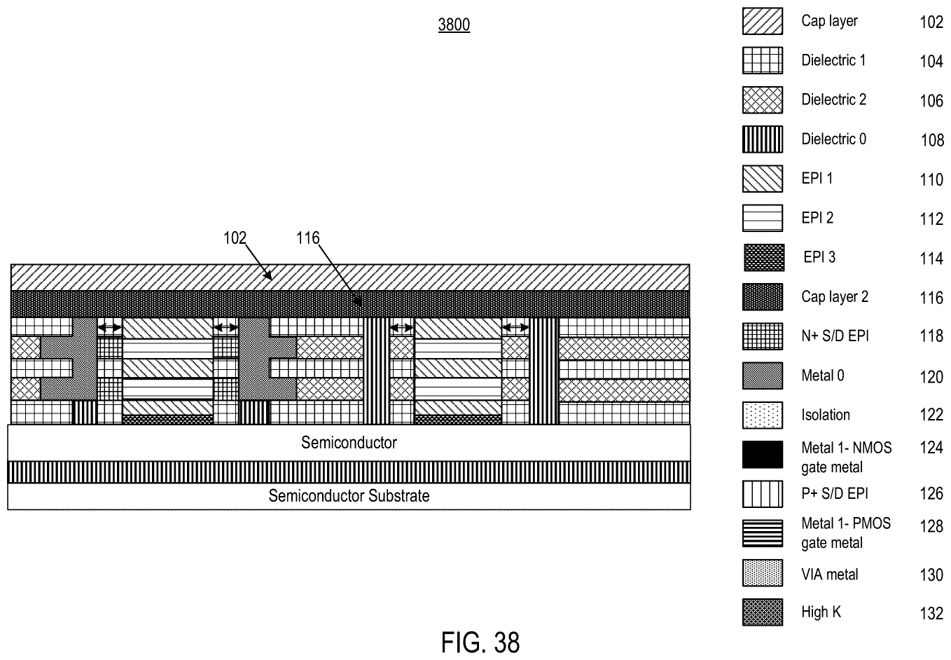

FIG. 38 illustrates a cross-sectional view 3800 of the next stage in the process flow. The capping layers 102, 116 (e.g., dual cap layer) can be deposited above the devices using at least one suitable deposition technique. The capping layer 116 can be deposited, followed by the capping layer 102.

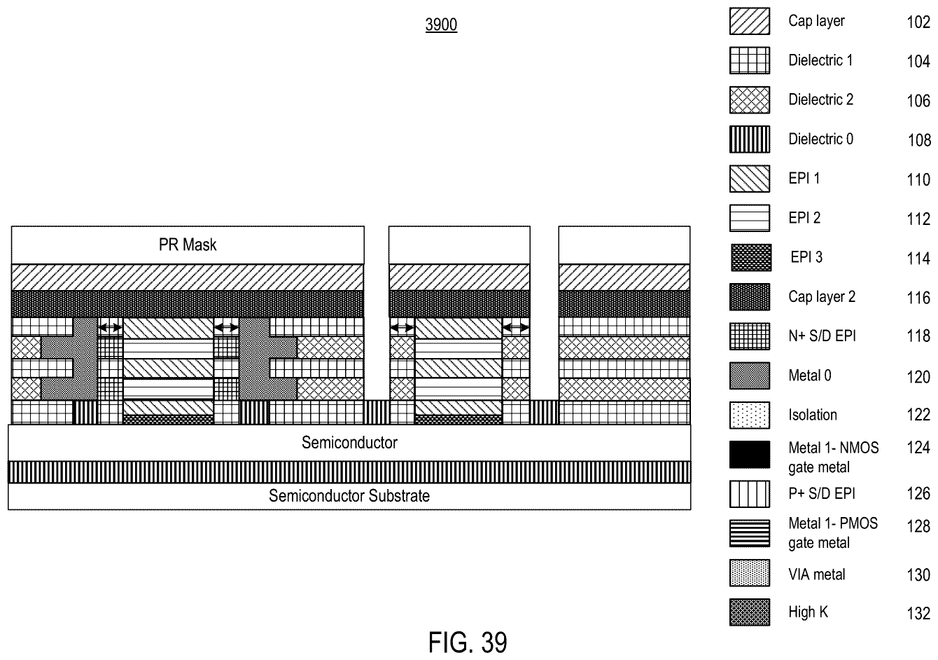

FIG. 39 illustrates a cross-sectional view 3900 of the next stage in the process flow. Similar processes or operations of the first semiconductor device can be performed for the second semiconductor device. For example, portions of the capping layers 102, 116 above the fifth and sixth portions (e.g., above the dielectric materials 108 adjacent to the third stack) of the first stack can be etched to form an opening. The capping layer 102, 116 can be used as a mask for etching the dielectric material 108. Via the opening of the capping layers 102, 116, a portion of the dielectric material 108 can be etched using at least one suitable etching technique. Etching the dielectric material 108 exposes the sidewalls of the dielectric materials 106 via the formed vertical channel openings.

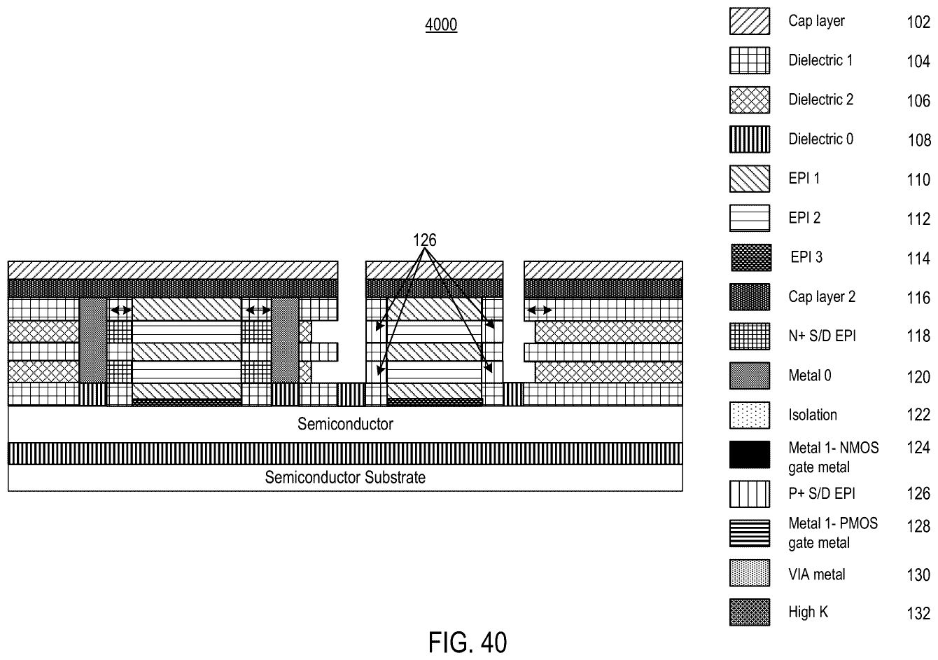

FIG. 40 illustrates a cross-sectional view 4000 of the next stage in the process flow. After forming the vertical channel opening, the dielectric materials 106 in contact with the sidewalls of the semiconductor materials 112 of the second semiconductor device can be replaced with an epitaxial material 126 (e.g., shown in the legend as “P+ S/D EPI”). For example, a lateral etching can be performed to remove the dielectric material 106 using at least one suitable etching technique. After forming the opening, the epitaxial material 126 (e.g., pair of third and fourth epitaxial structures) can be grown and in (e.g., electrical) contact with the semiconductor material 112. In some cases, the epitaxial material 126 may be etched to vertically align with the capping layers 102, 116. In some other cases, the epitaxial material 126 can extend into a portion of the vertical channel, for example. The epitaxial material 126 can be formed with similar or different materials from the epitaxial material 118. For example, the epitaxial material 126 may be formed with materials suitable for a PMOS device. The operation for replacing the dielectric material 106 with the epitaxial material 126 can be performed similarly to the operation of FIG. 36, for example.

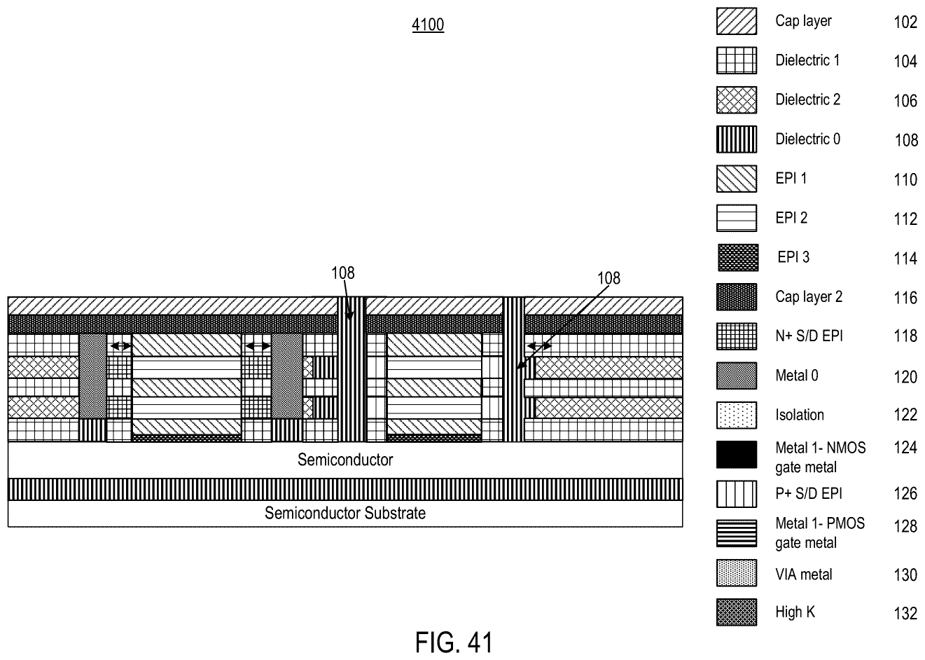

FIG. 41 illustrates a cross-sectional view 4100 of the next stage in the process flow. After growing the epitaxial material 126, the dielectric material 108 can be deposited into the vertical and lateral opening (e.g., the remaining opened portions). The dielectric material 108 can be deposited using at least one suitable deposition technique.

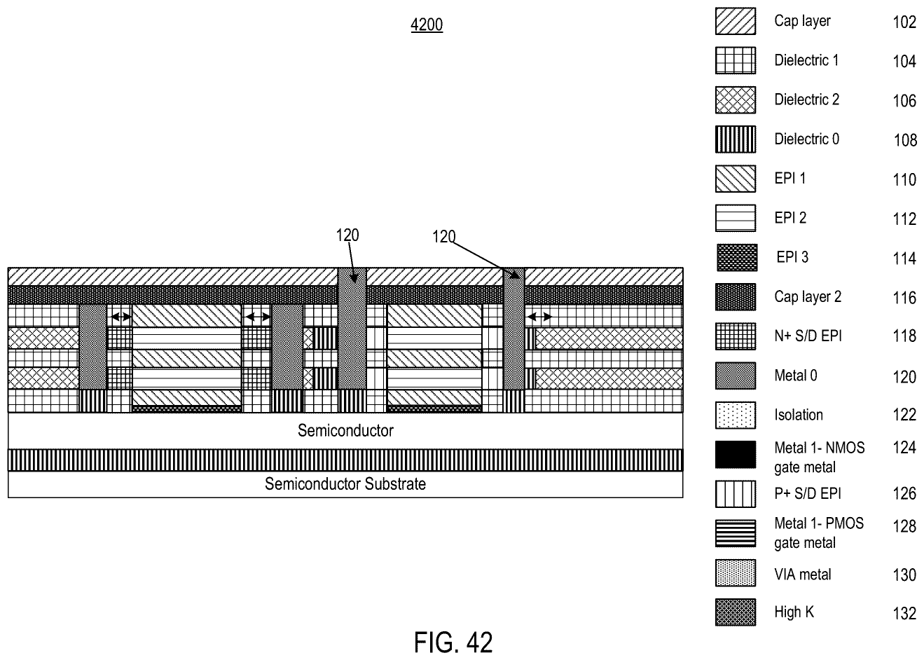

FIG. 42 illustrates a cross-sectional view 4200 of the next stage in the process flow. A portion of the dielectric material 108 deposited into the opening can be etched. For example, at least one suitable etching technique can be used to etched the dielectric material 108 from the top surface of the capping layer 102 to the bottom surface of the semiconductor material 112 (e.g., lateral alignment with the other materials). Etching the dielectric material 108 forms a vertical channel opening exposing the sidewalls of the epitaxial materials 126. As shown, the metal material 120 can be deposited in the vertical opening using at least one suitable deposition technique. The metal material 120 can extend vertically to the top surface of the capping layer 102. The metal material 120 can be in (e.g., electrical) contact with the dielectric material 108.

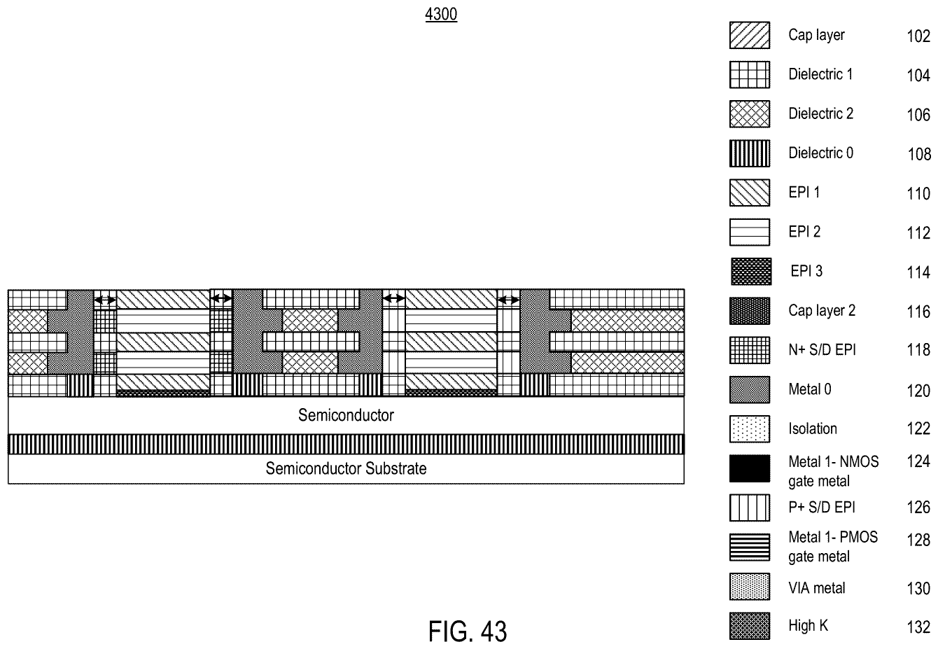

FIG. 43 illustrates a cross-sectional view 4300 of the next stage in the process flow. After depositing the metal material 120, the capping layers 102, 116 (e.g., hard masks) and a portion of the metal material 120 of the second semiconductor device can be removed using at least one suitable etching technique. The operation for removing the capping layers 102, 116 and the portion of the metal material 120 can be performed similarly to the operation described in FIG. 37.

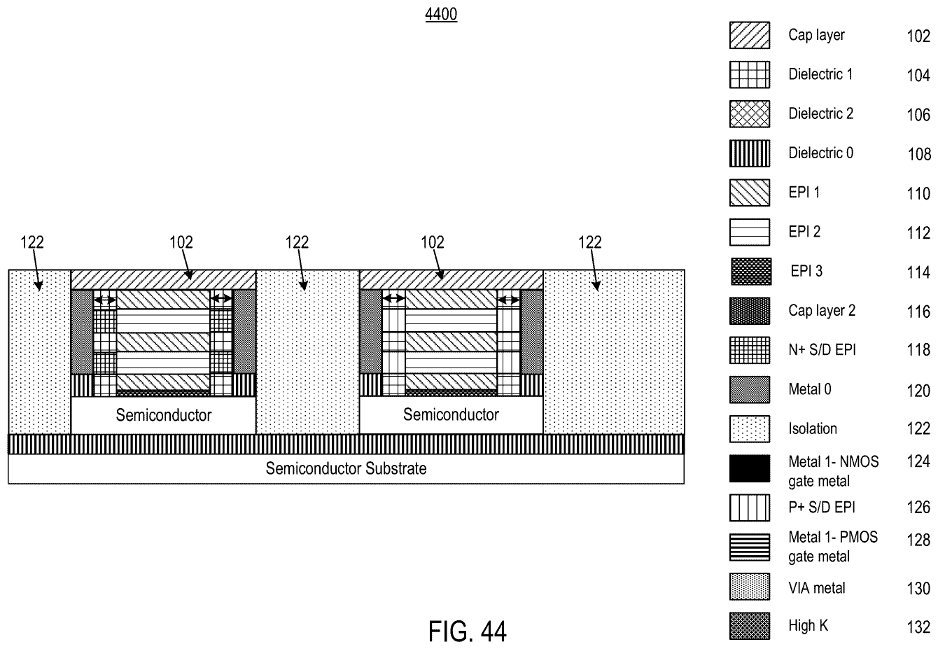

FIG. 44 illustrates a cross-sectional view 4400 of the next stage in the process flow. The capping layer 102 is deposited above the devices. After the deposition, portions of the capping layer 102 and the first stack are removed using at least one suitable etching technique. As shown, the removed portions of the first stack are adjacent to (e.g., to the sides of) the metal materials 120 (e.g., metal structures) of the respective second and third stacks. In some arrangements, portions of the semiconductor substrate that vertically align with these portions of the first stack can be removed. By removing the aforementioned portions, the surface of the dielectric material 108 (e.g., layered above a bottom one of the semiconductor substrates) can be exposed via the vertical channel opening.

After removing the portions of the first stack, the isolation material 122 can be deposited, such that the sidewalls of the semiconductor devices are in contact with the isolation material 122. Deposition of the isolation material 122 can be performed using at least one suitable selective deposition technique. The second and third stacks (e.g., first and second semiconductor devices) are isolated (e.g., laterally) from each other by the isolation material 122. As shown, the isolation material 122 can vertically extend from the surface of the dielectric material 108 to the top surface of the capping layer 102. In some cases, a suitable etching process may be utilized to etch the isolation material 122 to be flushed with the surface of the capping layer 102. The operations for removing portions of the first stack and the deposition of the isolation material 122 can be performed similarly to the operation described in FIG. 20, for example.

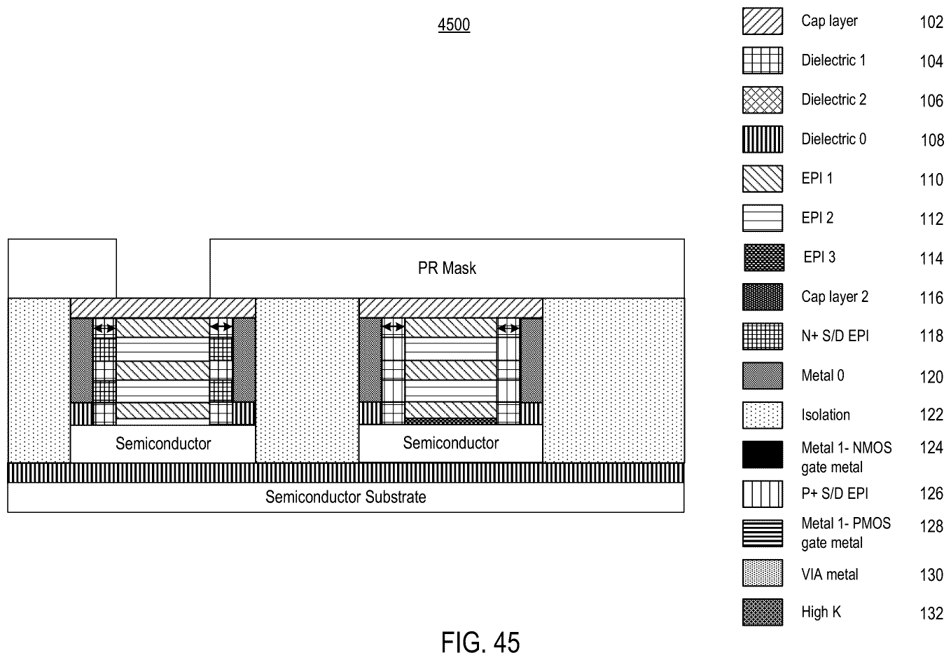

FIG. 45 illustrates a cross-sectional view 4500 of the next stage in the process flow. A mask including a predefined pattern can be deposited. The mask can include an opening aligned with the semiconductor material 114 (e.g., third semiconductor layer). Using the mask, the sidewall of the first semiconductor device (e.g., front and/or back of the device) can be etched down at least to the surface of the semiconductor substrate. Via the sidewall opening, the semiconductor material 114 can be removed using at least one suitable etching technique (e.g., lateral/horizontal etching of the semiconductor material 114. The mask can be removed after the etching process is performed. The operation for removing the semiconductor material 114 can be performed similarly to the operation described in at least FIG. 21, for example.

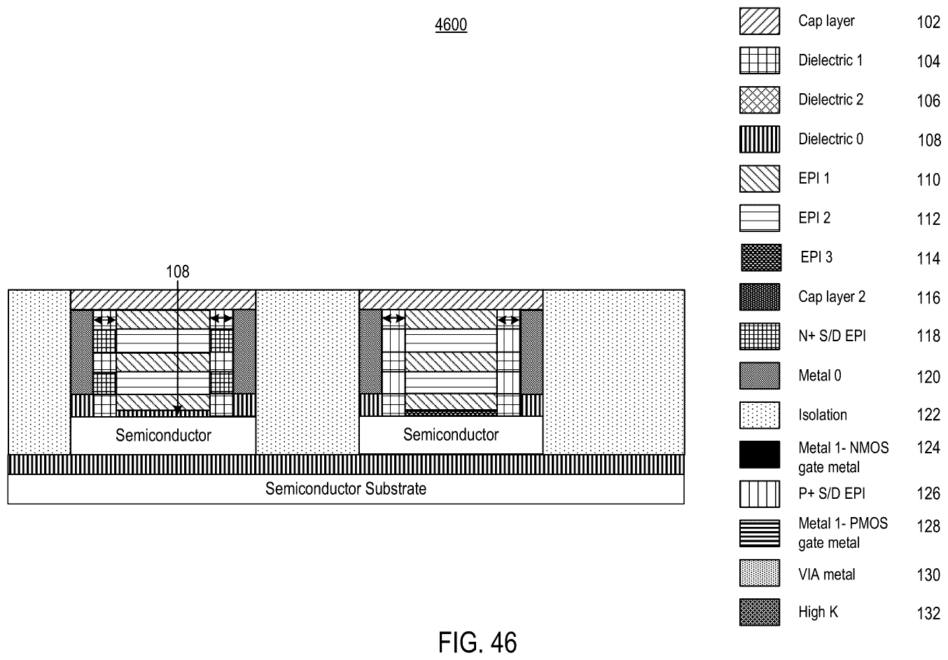

FIG. 46 illustrates a cross-sectional view 4600 of the next stage in the process flow. Via the opening formed by removing the semiconductor material 114, the dielectric material 108 can be deposited for the first semiconductor device. The dielectric material 108 can be deposited using at least one suitable deposition technique. Upon its deposition, the dielectric material 108 can be self-aligned with the capping layer 102. The dielectric material 108 isolates the second stack (e.g., including at least the semiconductor materials 110, 112, etc.) from the semiconductor substrate. The deposition of the dielectric material 108 can be performed similarly to the operation described in FIG. 22, for example.

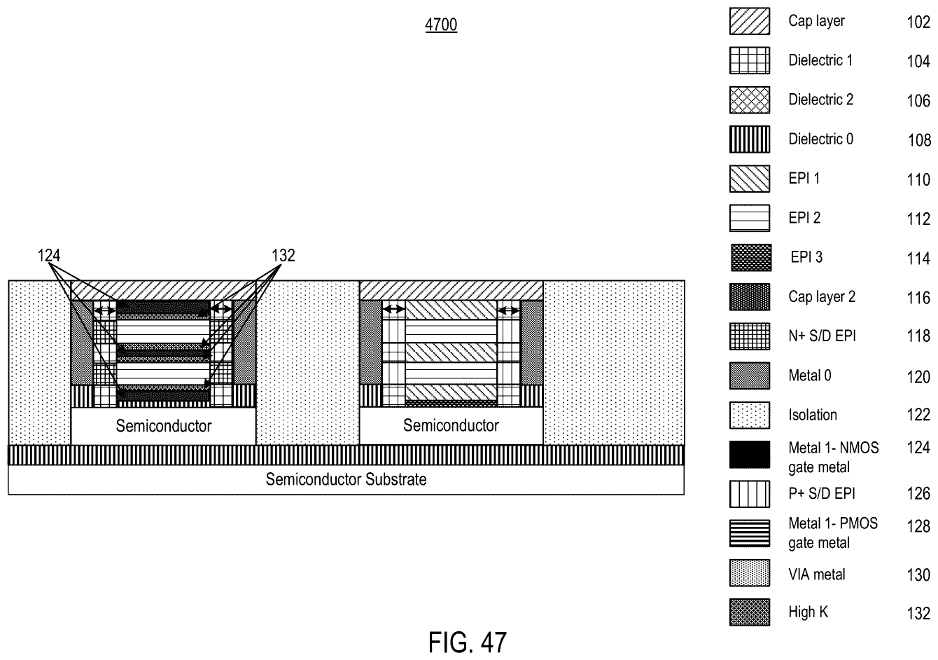

FIG. 47 illustrates a cross-sectional view 4700 of the next stage in the process flow. The semiconductor materials 110 (e.g., spacer layer) can be removed using at least a suitable etching technique. The semiconductor material 110 can assist with aligning the channel and S/D region with the gate structure, as described herein. Removing the semiconductor materials 110 exposes the surfaces (e.g., top and/or bottom surfaces) of the semiconductor material 112.

After removing the semiconductor materials 110, the removed portion of the second stack can be replaced or filled with metal material 124 and high-k dielectric material 132. The metal material 124 and/or the high-k dielectric material 132 can be deposited using at least one suitable deposition technique. The metal material 124 can be composed of any types of conductive material, which may be similar to or different from the metal material 120. In some arrangements, the metal material 124 may be used for an NMOS gate, or other types of gate (e.g., according to the type of transistors). The operation for removing and depositing the materials of FIG. 47 can be described similarly to the operation of FIGS. 23-24.

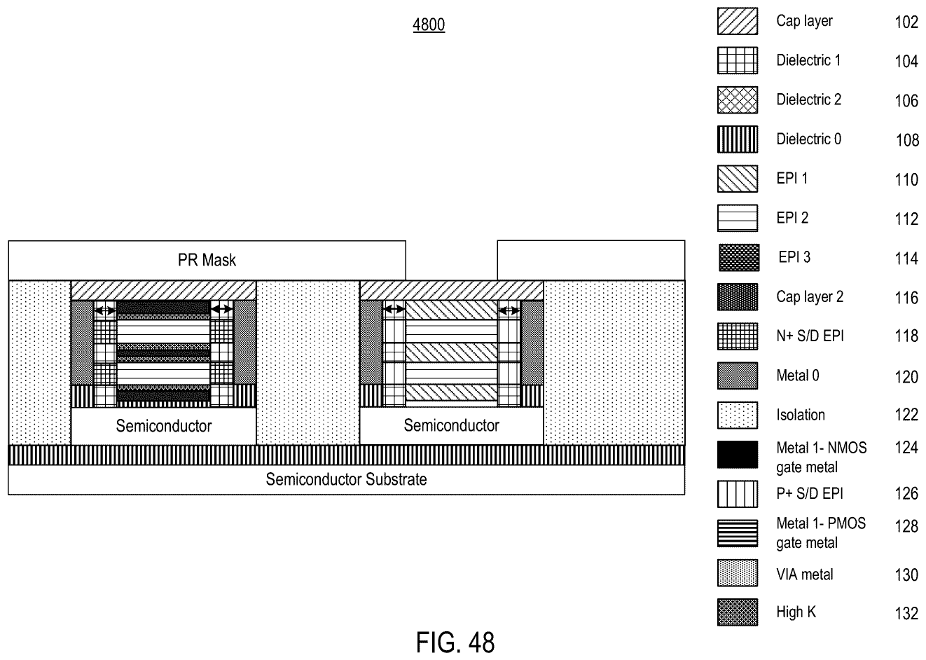

FIGS. 48-50 illustrate cross-sectional views 4800-5000 of the next stages in the process flow. The operations of FIGS. 48-50 can be performed similarly to the operations of FIGS. 45-47. For example, referring to cross-sectional view 4800, the semiconductor material 114 can be removed from the third stack (e.g., the second semiconductor device) using at least one suitable etching technique, e.g., including a predefined patterned mask.

Referring to cross-sectional view 4900, the dielectric material 108 can be deposited to replace the semiconductor material 114 using at least one suitable deposition technique. The dielectric material 108 can be vertically aligned with the structures of the third stack, such as the semiconductor materials 110, 112. Referring to cross-sectional view 5000, the semiconductor materials 110 (e.g., spacer layer) of the third stack can be removed using at least a suitable etching technique, thereby exposing the surfaces (e.g., top and/or bottom surfaces) of the semiconductor material 112. The semiconductor material 110 can assist with aligning the channel and S/D region with the gate structure, as described herein.

After removing the semiconductor materials 110, the removed portion of the third stack can be replaced or filled with metal material 128 (e.g., shown as “Metal 1-PMOS gate metal”) and high-k dielectric material 132. The metal material 128 and/or the high-k dielectric material 132 can be deposited using at least one suitable deposition technique. The metal material 128 can be composed of any types of conductive material, which may be similar to or different from the metal material 124. In some arrangements, the metal material 128 may be used for an PMOS gate, or other types of gate (e.g., according to the type of transistors).

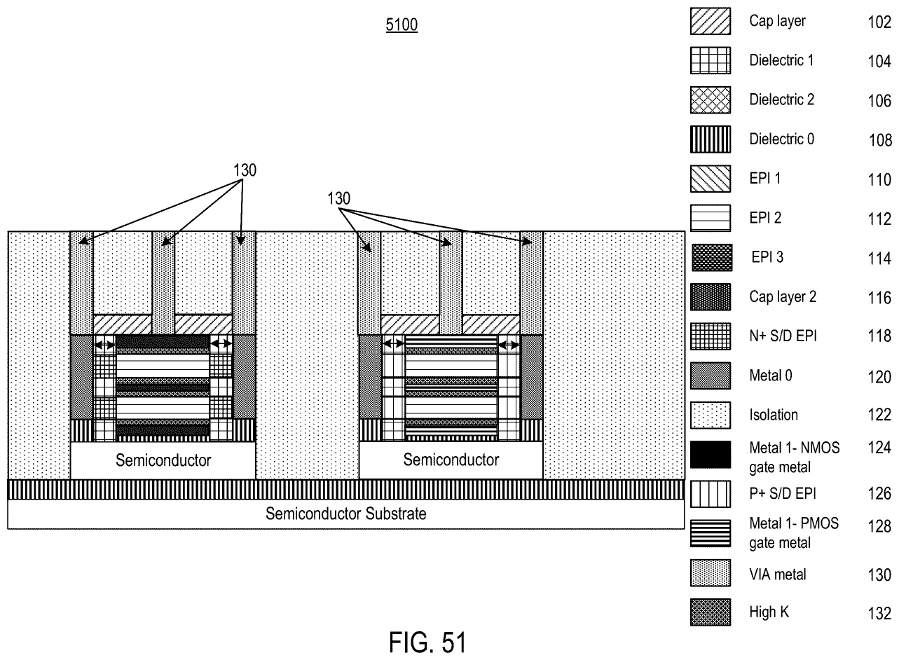

FIG. 51 illustrates a cross-sectional view 5100 of the next stages in the process flow. Following the deposition of the metal materials 124, 128 for the first and second semiconductor devices, respectively, the isolation material 122 can be deposited over the devices. Portions of the deposited isolation material 122 and the capping layer 102 can be etched, as shown in FIG. 51. The etched portions expose the surface of the S/D structures (e.g., metal materials 120) and gate structures (e.g., metal materials 124, 128) of the first and second semiconductor devices. The openings can be filled with via structures 130. The via structures 130 can be deposited using any suitable deposition technique. The via structures 130 can be in (e.g., electrical) contact with the respective materials or structures exposed through the openings (e.g., metal materials 120, 124, 128). The via structures 130 extend from the structures of the devices to at least the surface of the isolation material 122.

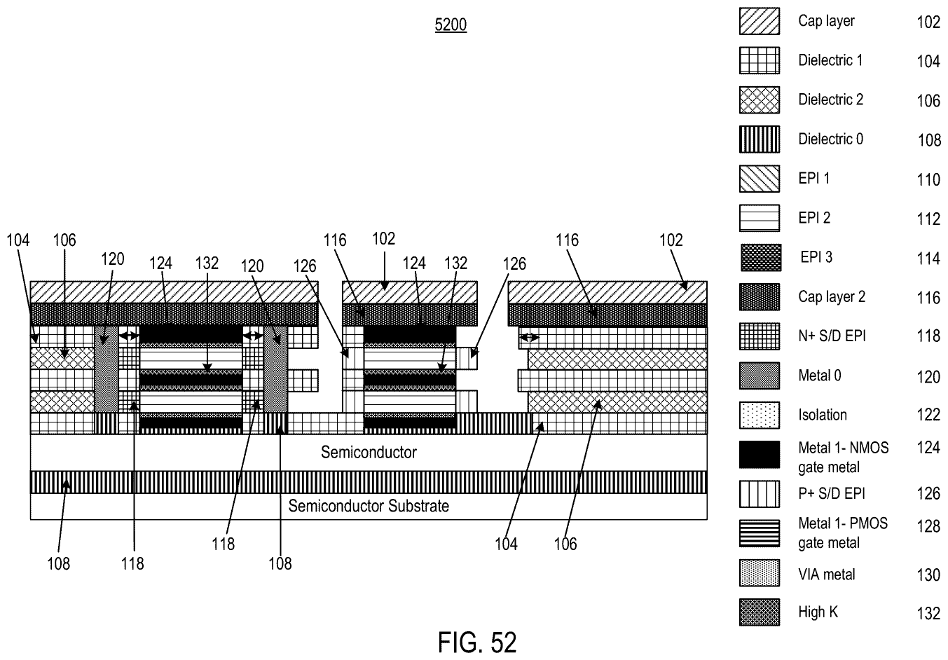

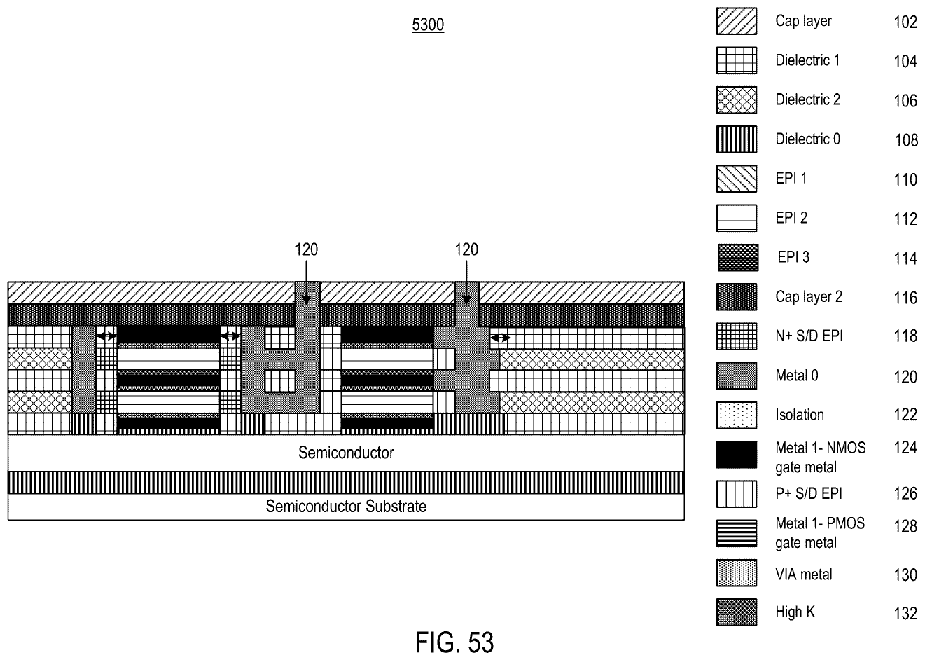

FIGS. 52-53 show various views 5200-5300 of a third process flow to manufacture semiconductor devices with integrated channel, source, and drain for an inverter. Each of FIGS. 52-53 generally refer to one or more process steps in a process flow, each of which is described in detail in connection with a respective Figure. For the purposes of simplicity and ease of visualization, some reference numbers may be omitted from some Figures. In FIGS. 52-53, an example process flow is described to manufacture a semiconductor device with connections between NMOS S/D and PMOS S/D functioning as an inverter.

The third process flow of FIGS. 52-53 can include operations, features, constructions, structures, or processes similar to one or more operations described in conjunction with at least one of FIGS. 1-51. For example, the operations of the third process flow can be performed using one or more similar techniques (e.g., etching, deposition, etc.) as at least FIGS. 1-51 of the first process flow or the second process flow.

FIG. 52 illustrates a cross-sectional view 5200 of a semiconductor device at a stage in the process flow. The structures shown in cross-section view 5200 can be formed or constructed using similar operations as described in at least FIGS. 27-40. For example, the semiconductor device of FIG. 52 can continue from the semiconductor device shown in FIG. 40. In this case, the lateral opening formed for the second semiconductor device can extend from the vertical opening to the metal material 120, thereby exposing the sidewall of the metal material 120 (e.g., in electrical contact with the epitaxial material 118). The lateral etching of the dielectric material 106 can be performed using at least one suitable etching technique.

FIG. 53 illustrates a cross-sectional view 5300 of the next stages in the process flow. After exposing the sidewall of the metal material 120 in (e.g., electrical) contact with the epitaxial material 118, the openings can be filled with additional metal material 120, as shown in FIG. 53. The additional metal material 120 can be deposited using at least one suitable deposition technique. The deposited metal material 120 extends the connection from the first semiconductor device (e.g., NMOS) to the second semiconductor device (e.g., PMOS). In this way, the metal material 120 can be in (e.g., electrical) contact with the epitaxial material 118 and the epitaxial material 126 (e.g., of NMOS and PMOS), which enables the semiconductor device to function as an inverter. In some cases, dielectric material 108 may be deposited and etched in the opening prior to the deposition of the metal material 120. Subsequent stages from FIG. 53 can be performed similarly to the operations described in at least one of FIG. 16-26 or 43-51, for example.

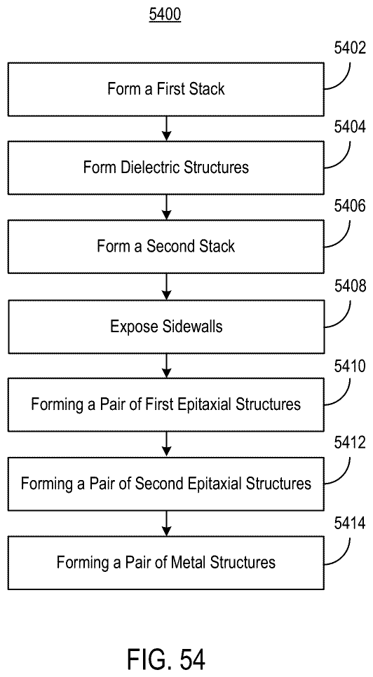

FIG. 54 illustrates a flow diagram of a method 5400 for microfabrication using the process flows described in connection with FIGS. 1-53, according to an embodiment. The method 5400 may include steps 5402-5414. However, other embodiments may include additional or alternative steps, or may omit one or more steps altogether.

Referring to step 5402, the method 5400 includes forming a first stack over a substrate. The first stack can include multiple first dielectric layers (e.g., dielectric material 104) and multiple second dielectric layers (e.g., dielectric material 106) alternately stacked on top of one another. In some cases, the first and second semiconductor layers refer to the semiconductor layers (e.g., dielectric material 106) of two devices. In this case, the first semiconductor layers can be vertically spaced from one another, and the second semiconductor layers can be vertically spaced from one another. The second semiconductor layers are laterally spaced from the first semiconductor layers, for example. The process for forming the first stack can be described in connection with at least one of FIG. 1 or 27, for example.

Referring to step 5404, the method 5400 includes forming dielectric structures (e.g., dielectric materials 108). For example, portions (e.g., first portion, second portion, and third portion) of the first stack can be replaced with a first dielectric structure, a second dielectric structure, and a third dielectric structure, respectively. The first to third dielectric structures each continuously (e.g., vertically) extend through the first stack. The second dielectric structure and the third dielectric structure can be disposed on opposite sides of the first dielectric structure, respectively. The process for forming the dielectric structures can be described in connection with at least one of FIG. 2, 3, or 29, for example.

Referring to step 5406, the method 5400 includes forming a second stack. The second stack is formed by replacing the first dielectric structure with various semiconductor layers, such as including first semiconductor layers (e.g., semiconductor material 110) and second semiconductor layers (e.g., semiconductor material 112) alternately stacked on top of one another. In various implementations, forming the second stack includes epitaxially growing a third semiconductor layer (e.g., semiconductor material 114) from the substrate, epitaxially growing a lower one of the first semiconductor layers, epitaxially growing the lower second semiconductor layer, epitaxially growing a middle one of the first semiconductor layers, epitaxially growing the upper second semiconductor layer, and epitaxially growing an upper one of the first semiconductor layers. The process for forming the second stack can be described in connection with at least one of FIG. 5 or 31, for example.

Referring to step 5408, the method 5400 includes exposing the sidewalls of each of the second semiconductor layers. Exposing the sidewalls of each of the second semiconductor layers, respectively, can be through removing a portion of the second dielectric structure and a portion of the third dielectric structure. The process for exposing the sidewalls of the second semiconductor layers can be described in connection with at least one of FIG. 11, 35, 40, or 52, for example.

Referring to step 5410, the method 5400 includes forming a pair of first epitaxial structures (e.g., epitaxial material 118). The formed pair of first epitaxial structures can be in contact with the exposed sidewalls of a lower one of the second semiconductor layers, respectively.

Referring to step 5412, the method 5400 includes forming a pair of second epitaxial structures (e.g., epitaxial material 118). The formed pair of second epitaxial structures can be in contact with the exposed sidewalls of an upper one of the second semiconductor layers, respectively. The process for forming the pair of first or second epitaxial structures can be described in connection with at least one of FIG. 12-14, 36, or 40, for example.

In some implementations, the pair of first epitaxial structures and the pair of second epitaxial structures can be concurrently formed. The pair of first epitaxial structures and the pair of second epitaxial structures can have the same conductive type (e.g., for NMOS, PMOS, or others). In some cases, the pair of first epitaxial structures and the pair of second epitaxial structures each have a first thickness thinner than a second thickness of each the second semiconductor layers. In some cases, the pair of first epitaxial structures and the pair of second epitaxial structures each have a similar thickness as the second semiconductor layers.

Referring to step 5414, the method 5400 includes forming a pair of metal structures (e.g., metal material 120). The pair of metal structures can be formed through the removed portion of the second dielectric structure and the removed portion of the third dielectric structure. The pair of metal structures can be in (e.g., electrical) contact with the pair of first epitaxial structures, respectively, and with the pair of second epitaxial structures, respectively. The process for forming the pair of metal structures can be described in connection with at least one of FIG. 15, 42, or 53, for example.

In various arrangements, the third semiconductor layer is replaced with a third dielectric layer (e.g., dielectric material 108) to electrically isolate the second stack from the substrate. The first semiconductor layers may be replaced with a gate structure (e.g., including at least one of metal material 124 or high-k dielectric material 132) that is around each of the second semiconductor layers. The process for forming the third dielectric layer and forming the gate structure can be described in connection with at least one of FIG. 22-24 or 45-50, for example.

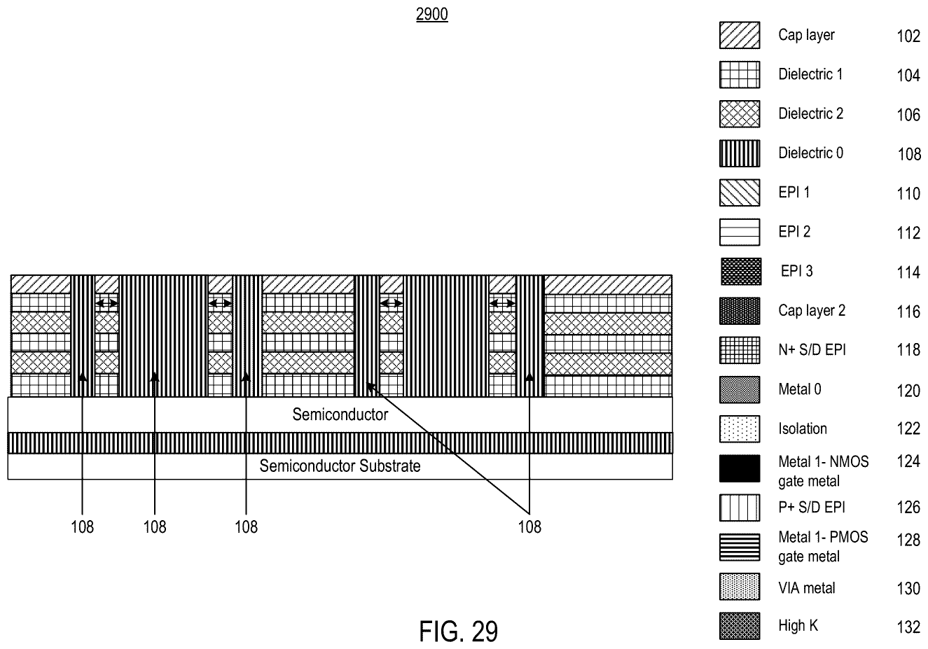

In some arrangements, portions of the first stack including a first portion, a second portion, a third portion, a fourth portion, a fifth portion, and a sixth portion can be replaced with a first dielectric structure, a second dielectric structure, a third dielectric structure, a fourth dielectric structure, a fifth dielectric structure, and a sixth dielectric structure, respectively. The first, second, and third portions can be associated with a first semiconductor device and the fourth, fifth, and sixth portions can be associated with a second semiconductor device. The first to sixth dielectric structures each continuously (e.g., vertically) extend through the first stack. The first dielectric structure can be interposed between the second and third dielectric structures (e.g., laterally interposed). The fourth dielectric structure can be interposed between the fifth and sixth dielectric structures. The process for forming these dielectric structures (e.g., dielectric material 108 for the first and second semiconductor devices) can be described in connection with at least one of FIGS. 28-29, for example.

In various arrangements, the first dielectric structure can be replaced with a second stack (e.g., associated with the first semiconductor device). The fourth dielectric structure can be replaced with a third stack (e.g., associated with the second semiconductor device). The second stack and third stack each include various first semiconductor layers and second semiconductor layers alternately stacked on top of one another.

For example, replacing the first dielectric structure with the second stack and replacing the fourth dielectric structure with the third stack can include epitaxially growing, in each of the first and fourth portions of the first stack, a third semiconductor layer from the substrate, epitaxially growing, in each of the first and fourth portions of the first stack, a lower one of the first semiconductor layers, epitaxially growing, in each of the first and fourth portions of the first stack, the lower second semiconductor layer, epitaxially growing, in each of the first and fourth portions of the first stack, a middle one of the first semiconductor layers, epitaxially growing, in each of the first and fourth portions of the first stack, the upper second semiconductor layer, and epitaxially growing, in each of the first and fourth portions of the first stack, an upper one of the first semiconductor layers. The process for forming the second and third stacks can be described in connection with at least FIG. 31, for example.

In various implementations, the second dielectric structure and the third dielectric structure can be removed. Through the removed portions, pairs of first epitaxial structures (e.g., epitaxial material 118) can be formed in contact with sidewalls of the second semiconductor layers of the second stack, respectively. The pairs of first epitaxial structures can be vertically spaced from one another. Each of the pairs of first epitaxial structures can be in contact with a corresponding one of the first semiconductor layers, respectively. In this case, the first semiconductor layers refer to the semiconductor materials 112 of the second stack.

In various implementations, the fifth dielectric structure and the sixth dielectric structure can be removed. Through the removed portions, the pairs of second epitaxial structures can be formed in contact with sidewalls of the second semiconductor layers of the third stack, respectively. In this case, the second semiconductor layers can refer to the semiconductor materials 112 of the third stack. The pairs of second epitaxial structures can be vertically spaced from one another. Each of the pairs of second epitaxial structures can be in contact with a corresponding one of the second semiconductor layers, respectively. The process for forming the pairs of first and second epitaxial structures can be described in connection with at least one of FIG. 36 or 40, for example.

In various arrangements, the pairs of first epitaxial structures each have a first conductive type and the pairs of second epitaxial structures each have a second conductive type. The first conductive type can be opposite to the second conductive type. By having the opposite conductive type, the semiconductor device can function as a CMOS or an inverter, for example.

In various implementations, through the respectively removed portions of the second dielectric structure and the third dielectric structure, a pair of first metal structures (e.g., metal materials 120 associated with the second stack) can be formed in (e.g., electrical) contact with each of the pairs of first epitaxial structures, respectively. Further, through the respectively removed portions of the fifth dielectric structure and the sixth dielectric structure, a pair of second metal structures (e.g., metal materials 120 associated with the third stack) can be formed in (e.g., electrical) contact with each of the pairs of second epitaxial structures, respectively. In some implementations, the third semiconductor layer in each of the first and fourth portions of the first stack with a respective third dielectric layer (e.g., dielectric material 108). In certain arrangements, the pair of first metal structures and the pair of second metal structures can be in (e.g., electrical) contact with each other, such as for the semiconductor device to function as an inverter. The process for forming the pairs of metal structures and the third dielectric layer can be described in connection with at least one of FIG. 37, 41, 45, 46, 48, or 49, for example.

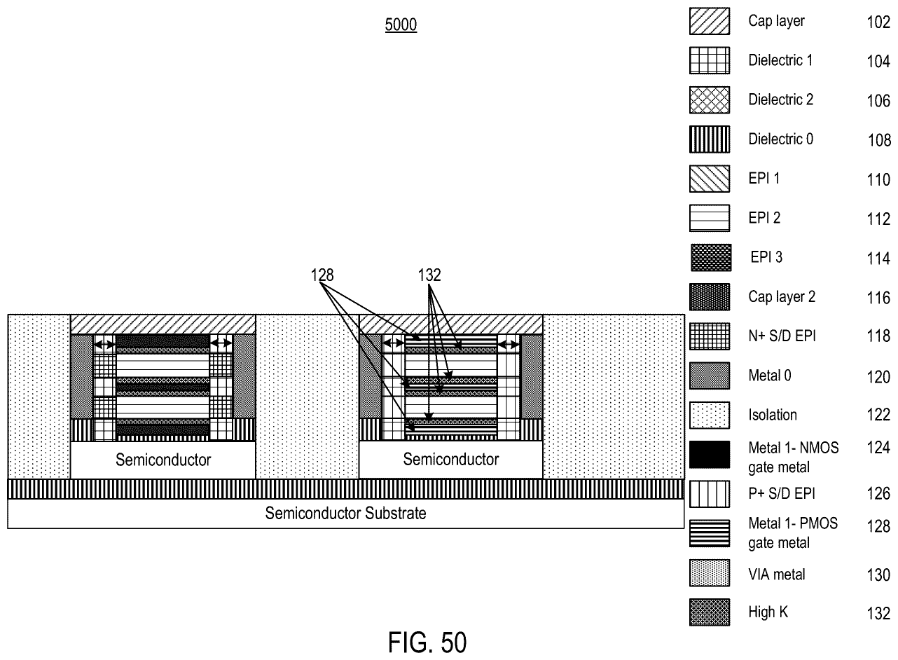

In certain implementations, the first semiconductor layers of the second stack can be replaced with a first gate structure that is around each of its second semiconductor layers (e.g., sometimes referred to as first semiconductor layers) of the second stack. Further, the first semiconductor layers of the third stack can be replaced with a second gate structure that is around each of its second semiconductor layers of the third stack. The first gate structure can have a first conductive type and the second gate structure can have a second conductive type. In some cases, the first conductive type can be opposite to the second conductive type, such that the semiconductor device can function as a CMOS or an inverter, for example. The process for forming the gate structures can be described in connection with at least one of FIG. 47 or 50, for example. The formation of other structures can be performed using the techniques described in connection with at least one of FIGS. 1-54, as described herein.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method for fabricating semiconductor devices, comprising:
forming a first stack over a substrate, the first stack including a plurality of first dielectric layers and a plurality of second dielectric layers alternately stacked on top of one another;
replacing a first portion, a second portion, and a third portion of the first stack with a first dielectric structure, a second dielectric structure, and a third dielectric structure, respectively, wherein the first, second, and third dielectric structures each continuously extend through the first stack;
replacing the first dielectric structure with a second stack, the second stack including a plurality of first semiconductor layers and a plurality of second semiconductor layers alternately stacked on top of one another;
removing a portion of the second dielectric structure;
removing a portion of the third dielectric structure;
exposing, through the removed portion of the second dielectric structure and the removed portion of the third dielectric structure, sidewalls of each of the plurality of second semiconductor layers, respectively;
forming a pair of first epitaxial structures in contact with the exposed sidewalls of a lower one of the second semiconductor layers, respectively; and
forming a pair of second epitaxial structures in contact with the exposed sidewalls of an upper one of the second semiconductor layers, respectively.

2. The method of claim 1, wherein the pair of first epitaxial structures and the pair of second epitaxial structures are concurrently formed, and wherein the pair of first epitaxial structures and the pair of second epitaxial structures have a same conductive type.

3. The method of claim 2, further comprising forming, through the removed portion of the second dielectric structure and the removed portion of the third dielectric structure, a pair of metal structures in electrical contact with the pair of first epitaxial structures, respectively, and with the pair of second epitaxial structures, respectively.

4. The method of claim 1, further comprising replacing the first semiconductor layers with a gate structure that is around each of the second semiconductor layers.

5. The method of claim 1, wherein the step of replacing the first dielectric structure with a second stack further comprises:
epitaxially growing a third semiconductor layer from the substrate;
epitaxially growing a lower one of the first semiconductor layers;
epitaxially growing the lower second semiconductor layer;
epitaxially growing a middle one of the first semiconductor layers;
epitaxially growing the upper second semiconductor layer; and
epitaxially growing an upper one of the first semiconductor layers.

6. The method of claim 5, further comprising replacing the third semiconductor layer with a third dielectric layer to electrically isolate the second stack from the substrate.

7. The method of claim 1, wherein the second dielectric structure and the third dielectric structure are disposed on opposite sides of the first dielectric structure, respectively.

8. The method of claim 1, wherein the pair of first epitaxial structures and the pair of second epitaxial structures each have a first thickness thinner than a second thickness of each the second semiconductor layers.

9. A method for fabricating semiconductor devices, comprising:
forming a first stack over a substrate, the first stack including a plurality of first dielectric layers and a plurality of second dielectric layers alternately stacked on top of one another;
replacing a first portion, a second portion, a third portion, a fourth portion, a fifth portion, and a sixth portion of the first stack with a first dielectric structure, a second dielectric structure, a third dielectric structure, a fourth dielectric structure, a fifth dielectric structure, and a sixth dielectric structure, respectively, wherein the first to sixth dielectric structures each continuously extend through the first stack, the first dielectric structure is interposed between the second and third dielectric structures, and the fourth dielectric structure is interposed between the fifth and sixth dielectric structures;
replacing the first dielectric structure with a second stack and replacing the fourth dielectric structure with a third stack, the second stack and third stack each including a plurality of first semiconductor layers and a plurality of second semiconductor layers alternately stacked on top of one another;
forming, through at least respectively removed portions of the second dielectric structure and the third dielectric structure, a plurality of pairs of first epitaxial structures in contact with sidewalls of the second semiconductor layers of the second stack, respectively; and
forming, through at least respectively removed portions of the fifth dielectric structure and the sixth dielectric structure, a plurality of pairs of second epitaxial structures in contact with sidewalls of the second semiconductor layers of the third stack, respectively.

10. The method of claim 9, wherein the pairs of first epitaxial structures each have a first conductive type and the pairs of second epitaxial structures each have a second conductive type.

11. The method of claim 10, wherein the first conductive type is opposite to the second conductive type.

12. The method of claim 9, further comprising:
replacing the first semiconductor layers of the second stack with a first gate structure that is around each of its second semiconductor layers; and
replacing the first semiconductor layers of the third stack with a second gate structure that is around each of its second semiconductor layers.

13. The method of claim 12, wherein the first gate structure has a first conductive type and the second gate structure has a second conductive type.

14. The method of claim 13, wherein the first conductive type is opposite to the second conductive type.

15. The method of claim 9, wherein the step of replacing the first dielectric structure with a second stack and replacing the fourth dielectric structure with a third stack comprises:
epitaxially growing, in each of the first and fourth portions of the first stack, a third semiconductor layer from the substrate;
epitaxially growing, in each of the first and fourth portions of the first stack, a lower one of the first semiconductor layers;
epitaxially growing, in each of the first and fourth portions of the first stack, the lower second semiconductor layer;
epitaxially growing, in each of the first and fourth portions of the first stack, a middle one of the first semiconductor layers;
epitaxially growing, in each of the first and fourth portions of the first stack, the upper second semiconductor layer; and
epitaxially growing, in each of the first and fourth portions of the first stack, an upper one of the first semiconductor layers.

16. The method of claim 15, further comprising:
replacing the third semiconductor layer in each of the first and fourth portions of the first stack with a respective third dielectric layer.

17. The method of claim 9, further comprising:
forming, through the respectively removed portions of the second dielectric structure and the third dielectric structure, a pair of first metal structures in electrical contact with each of the pairs of first epitaxial structures, respectively; and
forming, through the respectively removed portions of the fifth dielectric structure and the sixth dielectric structure, a pair of second metal structures in electrical contact with each of the pairs of second epitaxial structures, respectively.

18. A semiconductor device, comprising:
a plurality of first semiconductor layers vertically spaced from one another;
a plurality of second semiconductor layers vertically spaced from one another, wherein the second semiconductor layers are laterally spaced from the first semiconductor layers;
a plurality of pairs of first epitaxial structures vertically spaced from one another, wherein each of the pairs of first epitaxial structures are in contact with a corresponding one of the first semiconductor layers, respectively;
a plurality of pairs of second epitaxial structures vertically spaced from one another, wherein each of the pairs of second epitaxial structures are in contact with a corresponding one of the second semiconductor layers, respectively;
a first gate structure disposed around each of the first semiconductor layers; and
a second gate structure disposed around each of the second semiconductor layers.

19. The semiconductor device of claim 18, wherein the pairs of first epitaxial structures each have a first conductive type, and the pairs of second epitaxial structures each have a second conductive type.

20. The semiconductor device of claim 19, wherein the first conductive type is opposite to the second conductive type.
